(19) United States
(12) Patent Application Publication
(10) Pub. No.: US 2024/0384413 A1
(43) Pub. Date: Nov. 21, 2024

(54) SHOWERHEAD ASSEMBLY FOR CYCLIC VAPOR DEPOSITION WITH ENHANCED GAS MIXING

(71) Applicant: Eugenus, Inc., San Jose, CA (US)

(72) Inventors: Martin J. Salinas, Campbell, CA (US); Miguel Saldana, Santa Cruz, CA (US); Victor Calderon, Santa Clara, CA (US); H. William Lucas, JR., Santa Cruz, CA (US); Seyed Hossein Hashemi, San Ramon, CA (US); Vinay Shankar Vidyarthi, Fremont, CA (US)

(21) Appl. No.: 18/664,217

(22) Filed: May 14, 2024

Related U.S. Application Data
(60) Provisional application No. 63/502,564, filed on May 16, 2023.

(51) Int. Cl. C23C 16/455

(52) U.S. Cl. CPC C23C 16/45565; C23C 16/45512; C23C 16/45544

(57) ABSTRACT

A showerhead assembly configured to deliver a plurality of gases into a cyclic deposition chamber comprises a showerhead comprising a vertical cavity formed through a central region and a main inner surface configured to face a substrate. The main inner surface radially surrounds the vertical cavity and is tapered such that a vertical distance from the substrate to the main inner surface decreases in a radially outward direction relative a center of the substrate. The showerhead assembly additionally comprises an injector block assembly disposed over the showerhead for delivering the gases from outside of the cyclic deposition chamber into the cyclic deposition chamber through the vertical cavity. The showerhead assembly further comprises a plurality of gas channels formed in the injector block assembly.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

This application claims the priority benefit under 35 U.S.C. § 119 (e) to U.S. Provisional Patent Application No. 63/502,564, filed May 16, 2023, entitled “SHOWERHEAD ASSEMBLY FOR CYCLIC VAPOR DEPOSITION WITH ENHANCED GAS MIXING,” the content of which is hereby expressly incorporated by reference in its entirety.

### BACKGROUND

### Field

The disclosed technology relates generally to thin film deposition systems, and more particularly to showerhead assemblies for cyclic vapor deposition systems.

### Description of the Related Art

As semiconductor devices continue to scale in lateral dimensions, there is a corresponding scaling of vertical dimensions of the semiconductor devices, including thickness scaling of the functional thin films such as electrodes and dielectrics. Semiconductor fabrication involves various thin films that are deposited and patterned throughout the process flow. The thin films employed in semiconductor fabrication can be formed using various techniques, including wet and dry deposition methods. Wet deposition methods include, e.g., aerosol/spray deposition, sol-gel method and spin-coating. Dry deposition methods include physical vapor-based techniques, e.g., physical vapor deposition (PVD) and evaporation. Dry deposition methods additionally include precursor and/or chemical reaction-based techniques, e.g., chemical vapor deposition (CVD) and cyclic deposition such as atomic layer deposition (ALD).

### SUMMARY

In one aspect, a showerhead assembly configured to deliver a plurality of gases into a cyclic deposition chamber comprises a showerhead comprising a vertical cavity formed through a central region and a main inner surface configured to face a substrate. The showerhead assembly additionally comprises an injector block assembly disposed over the showerhead for delivering the gases from outside of the cyclic deposition chamber into the cyclic deposition chamber through the vertical cavity. The showerhead assembly further comprises a plurality of gas channels formed in the injector block assembly and configured to flow the gases separately at least partly through the injector block assembly. The gas channels exiting the injector block assembly extend in different directions relative to each other and to a vertical axis crossing the substrate.

In another aspect, a showerhead assembly configured to deliver a plurality of gases into a cyclic deposition chamber comprises a showerhead comprising a vertical cavity formed through a central region and a main inner surface configured to face a substrate. The showerhead assembly additionally comprises an injector block assembly disposed over the showerhead for delivering the gases from outside of the cyclic deposition chamber into the cyclic deposition chamber through the vertical cavity. The showerhead assembly further comprises a plurality of gas channels formed in the injector block assembly and configured to flow the gases separately at least partly through the injector block assembly. A neck angle formed between the main surface and a horizontal plane parallel to a main surface of the substrate is 2-7 degrees.

In another aspect, a showerhead assembly configured to deliver a plurality of gases into a cyclic deposition chamber comprises a showerhead comprising a vertical cavity formed through a central region and a main inner surface configured to face a substrate. The showerhead assembly additionally comprises an injector block assembly disposed over the showerhead for delivering the gases from outside of the cyclic deposition chamber into the cyclic deposition chamber through the vertical cavity. The showerhead assembly further comprises a plurality of gas channels formed in the injector block assembly and configured to flow the gases separately at least partly through the injector block assembly. The vertical cavity has a volume having a shape of a truncated cone, wherein the gases enter the vertical cavity through a narrower top portion and exits into the cyclic deposition chamber through a base portion of the truncated cone wider than the top portion.

In another aspect, a showerhead assembly configured to deliver a plurality of gases into a cyclic deposition chamber comprises a showerhead comprising a vertical cavity formed through a central region and a main inner surface configured to face a substrate. The showerhead assembly additionally comprises an injector block assembly disposed over the showerhead for delivering the gases from outside of the cyclic deposition chamber into the cyclic deposition chamber through the vertical cavity. The showerhead assembly further comprises a plurality of gas channels formed in the injector block assembly and configured to flow the gases separately at least partly through the injector block assembly. The showerhead assembly further comprises a premix chamber formed in the injector block assembly, where the premix chamber is configured to receive the gases separately through the gas channels and to premix the gases therein to form a gas mixture before the gas mixture is delivered to the vertical cavity.

In another aspect, a showerhead assembly configured to deliver a plurality of gases into a cyclic deposition chamber comprises a showerhead comprising a main inner surface configured to face a substrate, wherein the main inner surface surrounds a vertical cavity formed at a central region thereof through which the gases are delivered into the cyclic deposition chamber. The showerhead assembly additionally comprises an injector block assembly disposed over the showerhead and configured to receive the gases through external gas lines connected thereto and having a plurality of injection nozzles to deliver the gases into the cyclic deposition chamber through the vertical cavity. The showerhead assembly further comprises a premix chamber formed in the injector block assembly, where the premix chamber is configured to premix the gases received from the gas lines to form a gas mixture therein before the gas mixture is delivered to the vertical cavity. An internal volume of the premix chamber has a constricted portion that constricts the gas mixture prior to delivering the gas mixture to the vertical cavity.

In another aspect, a showerhead assembly configured to deliver a plurality of gases into a cyclic deposition chamber comprises a showerhead comprising a main inner surface configured to face a substrate, wherein the main inner surface surrounds a vertical cavity formed at a central region thereof through which the gases are delivered into the cyclic deposition chamber. The showerhead assembly additionally comprises an injector block assembly disposed over the showerhead and configured to receive the gases through external gas lines connected thereto and having a plurality of injection nozzles to deliver the gases into the cyclic deposition chamber through the vertical cavity. The showerhead assembly further comprises a premix chamber formed in the injector block assembly, where the premix chamber is configured to premix the gases received from the gas lines to form a gas mixture therein before the gas mixture is delivered to the vertical cavity. The premix chamber has a lower portion comprising a plurality of nozzles for injecting the gas mixture into the vertical cavity.

In another aspect, a showerhead assembly configured to deliver a plurality of gases into a cyclic deposition chamber comprises a showerhead comprising a main inner surface configured to face a substrate, wherein the main inner surface surrounds a vertical cavity formed at a central region thereof through which the gases are delivered into the cyclic deposition chamber. The showerhead assembly additionally comprises an injector block assembly disposed over the showerhead and configured to receive the gases through external gas lines connected thereto and having a plurality of injection nozzles to deliver the gases into the cyclic deposition chamber through the vertical cavity. The showerhead assembly further comprises a premix chamber formed in the injector block assembly, where the premix chamber is configured to premix the gases received from the gas lines to form a gas mixture therein before the gas mixture is delivered to the vertical cavity. A neck angle formed between the main surface and a horizontal plane parallel to a main surface of the substrate is 2-7 degrees.

In another aspect, a showerhead assembly configured to deliver a plurality of gases into a cyclic deposition chamber comprises a showerhead comprising a main inner surface configured to face a substrate, wherein the main inner surface surrounds a vertical cavity formed at a central region thereof through which the gases are delivered into the cyclic deposition chamber. The showerhead assembly additionally comprises an injector block assembly disposed over the showerhead and configured to receive the gases through external gas lines connected thereto and having a plurality of injection nozzles to deliver the gases into the cyclic deposition chamber through the vertical cavity. The showerhead assembly further comprises a premix chamber formed in the injector block assembly, where the premix chamber is configured to premix the gases received from the gas lines to form a gas mixture therein before the gas mixture is delivered to the vertical cavity. The vertical cavity has a volume having a shape of a truncated cone, wherein the gases enter vertical cavity through a narrower top portion and exits into the cyclic deposition chamber through a base portion of the truncated cone.

In another aspect, a showerhead assembly configured to deliver a plurality of gases into a cyclic deposition chamber comprises a showerhead comprising a main inner surface configured to face a substrate, wherein the main inner surface surrounds a vertical cavity formed at a central region thereof through which the gases are delivered into the cyclic deposition chamber. The showerhead assembly additionally comprises an injector block assembly disposed over the showerhead and configured to receive the gases through external gas lines connected thereto and having a plurality of injection nozzles for delivering the gases into the cyclic deposition chamber through the vertical cavity. The showerhead assembly further comprises a diffuser plate substantially overlapping a lateral footprint of the showerhead and disposed vertically between the showerhead and the substrate, the diffuser plate comprising a plurality of holes for diffusing the gases received from the vertical cavity prior to the gases reaching the substrate.

In another aspect, a showerhead assembly configured to deliver a plurality of gases into a cyclic deposition chamber comprises a showerhead comprising a main inner surface configured to face a substrate, wherein the main inner surface surrounds a vertical cavity formed at a central region thereof through which the gases are delivered into the cyclic deposition chamber. The showerhead assembly additionally comprises an injector block assembly disposed over the showerhead and configured to receive the gases through external gas lines connected thereto and having a plurality of injection nozzles for delivering the gases into the cyclic deposition chamber through the vertical cavity. The showerhead assembly further comprises a blocking plate disposed laterally at the central region and vertically between the injection nozzles and the substrate.

In another aspect, a showerhead assembly configured to deliver a plurality of gases into a cyclic deposition chamber comprises a showerhead comprising a main inner surface configured to face a substrate, wherein the main inner surface surrounds a vertical cavity formed at a central region thereof through which the gases are delivered into the cyclic deposition chamber. The showerhead assembly additionally comprises an injector block assembly disposed over the showerhead and configured to receive the gases through external gas lines connected thereto and having a plurality of injection nozzles for delivering the gases into the cyclic deposition chamber through the vertical cavity. The main inner surface of the showerhead forms an angle, with respect to a main surface of the substrate, that is different at different radial distances from a central axis of the showerhead.

In another aspect, a showerhead assembly configured to deliver a plurality of gases into a cyclic deposition chamber comprises a showerhead comprising a main inner surface configured to face a substrate, wherein the main inner surface surrounds a vertical cavity formed at a central region thereof through which the gases are delivered into the cyclic deposition chamber. The showerhead assembly additionally comprises an injector block assembly disposed over the showerhead and configured to receive the gases through external gas lines connected thereto and having a plurality of injection nozzles for delivering the gases into the cyclic deposition chamber through the vertical cavity. A vertical gap between the main inner surface of the showerhead and a main surface of the substrate changes nonlinearly with radial distance from a central axis of the showerhead.

### BRIEF DESCRIPTION OF THE DRAWINGS

FIG. 1 schematically illustrates a thin film deposition system including a deposition chamber configured to deliver precursors using a showerhead assembly, according to embodiments.

FIG. 2A illustrates a cross-sectional view of a showerhead assembly configured for improved precursor velocity and concentration uniformity at the substrate, according to some embodiments.

FIG. 2B illustrates design features for optimization of a showerhead assembly configured for improved precursor velocity and concentration uniformity at the substrate, according to some embodiments.

FIG. 2C illustrates a perspective view of a chamber lid assembly including the showerhead assembly illustrated in FIG. 2A, according to some embodiments.

FIG. 2D illustrates a perspective view of the thin film deposition chamber including a susceptor and a showerhead assembly illustrated in FIG. 1, according to some embodiments.

FIG. 2E illustrates an example gas injector block configuration and simulated gas flow trajectories in a vertical gas diffusion cavity of a showerhead assembly according to some embodiments.

FIG. 2F illustrates a surface of a showerhead of a showerhead assembly facing a susceptor, according to some embodiments.

FIG. 3 shows a perspective view of a top external portion of a deposition chamber including multiple processing stations each configured for a temperature-controlled showerhead assembly, according to some embodiments.

FIG. 4 shows a perspective view of an injector block assembly having formed therein a plurality of gas channels configured to flow the gases separately at least partly through the injector block assembly and into a vertical gas diffusion cavity at a vertical depth, according to some embodiments.

FIG. 5A shows a perspective view of an injector block assembly having formed therein a plurality of gas channels configured to flow the gases separately at least partly through the injector block assembly and into a premix chamber disposed in a vertical gas diffusion cavity, according to some embodiments.

FIG. 5B shows a perspective view of an injector block assembly having formed therein a plurality of gas channels configured to flow the gases separately at least partly through the injector block assembly and into a premix chamber disposed in a vertical gas diffusion cavity, according to some embodiments.

FIG. 5C shows a cross sectional view of exiting gas channels formed at a lower portion of the premix chambers of the injector block assemblies illustrated in FIGS. 5A and 5B, according to some embodiments.

FIG. 6A shows a perspective view of an injector block assembly having formed therein a plurality of gas channels configured to flow the gases separately at least partly through the injector block assembly and into a premix chamber disposed in the injector block assembly, according to some embodiments.

FIG. 6B shows perspective and cross-sectional views of the injector block assembly of FIG. 6A including source gas lines connected thereto.

FIG. 6C shows perspective and cross-sectional views of an injector block assembly having formed therein a plurality of gas channels configured to flow the gases separately at least partly through the injector block assembly and into a premix chamber disposed in the injector block assembly, according to some embodiments.

FIG. 7 illustrates an injector block assembly having formed therein a premix chamber configured to premix the gases received from the gas lines to form a gas mixture before the gas mixture is delivered to the vertical cavity, according to some embodiments.

FIG. 8 illustrates an injector block assembly having formed therein a premix chamber configured to premix the gases received from the gas lines to form a gas mixture before the gas mixture is delivered to the vertical cavity, according to some other embodiments.

FIG. 9A illustrates a side view of the thin film deposition chamber including a showerhead assembly having a diffuser plate, according to some embodiments.

FIG. 9B illustrates a major surface of the diffuser plate having a plurality of holes formed therein for diffusing gases.

FIG. 9C illustrates a side view of the diffuser plate shown in FIG. 9B.

FIGS. 10A-10C schematically illustrate different patterns of holes that can be implemented in the diffuser plate illustrated in FIGS. 9B and 9C.

FIG. 10D illustrates a major surface of the diffuser plate having a plurality of concentric radial zones, wherein different radial zones have differently arranged holes.

FIG. 11 illustrates a side view of the thin film deposition chamber including a showerhead assembly having a diffuser plate and a blocking plate, according to some embodiments.

FIG. 12A illustrates a flow pattern diagram of gases through a vertical cavity of a showerhead without a blocking plate.

FIG. 12B illustrates a flow pattern diagram of gases through a vertical cavity of a showerhead having a vertically elongated blocking plate, according to some embodiments.

FIG. 12C illustrates a flow pattern diagram of gases through a vertical cavity of a showerhead having a vertically elongated blocking plate, according to some other embodiments.

FIG. 13 illustrates a cross-sectional side view of the thin film deposition chamber including a showerhead assembly having a diffuser plate having mounted thereon a blocking plate, according to some embodiments.

FIG. 14 illustrates a side view of the thin film deposition chamber including a showerhead assembly having a main inner surface having an angle, with respect to a main surface of the substrate, that is different at different radial distances from a central axis of the showerhead, according to embodiments.

FIG. 15 illustrates an example precursor exposure and purge gas sequence for a deposition chamber configured for a temperature-controlled showerhead assembly, according to some embodiments.

FIG. 16 illustrates a schematic cross-sectional view of a conformal thin film formed in a high aspect ratio trench using a temperature-controlled showerhead assembly, according to some embodiments.

### DETAILED DESCRIPTION

Cyclic deposition processes such as atomic layer deposition (ALD) processes can provide a relatively conformal thin films on relatively high aspect-ratio (e.g., 2:1) structures with high uniformity and thickness precision. While generally less conformal and uniform compared to ALD, thin films deposited using continuous deposition processes such as chemical vapor deposition (CVD) can provide higher productivity and lower cost. ALD and CVD can be used to deposit a variety of different films including elemental metals, metallic compounds (e.g., TiN, TaN, etc.), semiconductors (e.g., Si, III-V, etc.), dielectrics (e.g., SiO₂, AlN, HfO₂, ZrO₂, etc.), rare-earth oxides, conducting oxides (e.g., IrO₂, etc.), ferroelectrics (e.g., PbTiO₃, LaNiO₃, etc.), superconductors (e.g., Yba₂Cu₃O₇₋ₓ), and chalcogenides (e.g., GeSbTe), to name a few.

Some cyclic deposition processes such as atomic layer deposition (ALD) include alternatingly exposing a substrate to a plurality of precursors to form a thin film. The different precursors can alternatingly at least partly saturate the surface of the substrate and react with each other, thereby forming the thin film in a layer-by-layer fashion. There are different types of ALD, including time-based ALD and spatial ALD. In a time-based ALD, precursors are injected sequentially, reacting one at a time with active sites on the substrate surface. The exposures to precursors may be separated by a purge step in order to prevent mixing and reaction of precursors in the gas phase. The reaction is thus surface-limited and self-terminating, yielding uniform deposition. In addition, many ALD processes can allow for deposition of high-quality materials at substantially lower temperatures than with CVD, even near room temperature. ALD growth can take place in a particular temperature window, below which precursor molecules may not be sufficiently activated, or desorption can be too slow, and above which precursors can decompose at the surface or even before reaching it, and desorption can be too fast during the purge step.

Because of the layer-by-layer growth capability, ALD can enable precise control of the thickness and the composition, which in turn can enable precise control of various properties such as conductivity, conformality, uniformity, barrier properties and mechanical strength. In particular, due to thickness scaling that often accompanies feature size scaling in semiconductor devices, there is an increasing need to improve the within-wafer uniformity even for ALD that is already known to produce thin films with very high uniformity relative to other techniques. Although ALD films generally have excellent uniformity, there may be several reasons why the uniformity could be degraded during deposition. The uniformity could be degraded due to, e.g., overlapping reactant pulses, non-uniform precursor distribution, thermal self-decomposition of precursors, and non-uniformities in substrate temperature, to name a few.

Non-uniform precursor distributions can be caused by limited diffusion or mixing with carrier gases. For example, in ALD reactors, the precursors are introduced to the reaction chamber from individual source delivery lines, and the lines may be brought together to a common in-feed line prior to being introduced into the reaction chamber. Without being bound to any theory, a carrier gas, which may be flowing through all precursor delivery lines, can sometimes result in the carrier gas from one precursor delivery line serving as a diffusion barrier for the precursor flowing from a different precursor delivery line. Although the precursor would get properly mixed with the carrier gas in the individual source delivery line, the precursor may not properly spread out beyond the intersection of the common reactor in-feed line that is usually located a short distance from the substrate in the upstream direction.

To mitigate these concerns, some reactor chambers employ a means for distributing precursor/reactant and purge gases within the reactor volume. One such means includes a showerhead employed to effectively distribute and mix gases including precursors. Design variations of this hardware can range from flat designs to tapered designs. Gas distribution can be provided in one of several ways, including (1) across the surface of the showerhead via a plurality of holes supplied by one or more plenums, (2) fed from the center of the showerhead or (3) from one end to the other (also referred to as cross-flow).

In order to reduce the above-noted non-uniformity issues arising from insufficient mixing or diffusion, some ALD reactors, e.g., reactors with flat showerheads and distributed holes, a larger spacing between the showerhead and the substrate to increase the mixing and diffusion and reduce the effects of gas impingement on the substrate. However, increased spacing between the showerhead and the substrate comes at a price of longer ALD cycle times due to increased volume to fill with gases and purge. In time-based ALD, longer time needed to fill and purge the reactor can also worsen the non-uniformity arising from overlapping reactant pulses, because there may be longer leading and trailing edges for precursor pulses. In spatial ALD reactors with flat showerheads, spacing can be smaller but there may also typically a leading and trailing edge effect.

Furthermore, even if designs can be improved such that the spacing between the showerhead and the substrate can be reduced, doing to may come at the price of other non-uniformity causes such as greater spatial and temporal temperature fluctuation at the showerhead. The inventors have found that, for the stringent requirements of today's semiconductor manufacturing specifications, such temperature fluctuation at the showerhead in turn causes temperature fluctuations at the substrate level, which translates to within-wafer nonuniformities of various parameters, including thickness, resistivity, step coverage, etc.

Thus, there is a need for precursor delivery systems designed for improved productivity (e.g., lower ALD cycle time) and uniformity of the thin films deposited in ALD systems. To address these and other sources of non-uniformities, various embodiments disclosed herein relate to a showerhead assembly configured for improved velocity and concentration uniformity of the precursors at the substrate.

### Cyclic Vapor Deposition Systems Configured for High Uniformity Showerhead Assembly

Various hardware design considerations for cyclic vapor deposition systems, e.g., ALD systems, are inter-dependent. A design optimization for one parameter can often result in degradation of another parameter. For example, it may be desirable to reduce the volume between a showerhead and the substrate that needs to be filled during an exposure of the substrate to a precursor, such that a shorter amount of time is needed to saturate the substrate surface with the precursor. However, the inventors have discovered that a reduction in the showerhead-to-substrate distance, without other adjustments, can sometimes significantly increase non uniformity of the velocity and concentration of the precursors at the surface of the substrate, thereby detrimentally impacting various properties of the resulting thin films. In particular, the inventors have discovered that a showerhead design for an ALD reactor can have a significant impact on the thickness, composition and physical property uniformity of the thin films deposited in an ALD reactor. Among others, the inventors have discovered that controlling the spatial concentration or flux profiles of the precursors at the substrate surface, as well as maintaining a relatively uniform velocity distribution of the precursor molecules, can be important for reducing non-uniformities in the resulting thin films deposited by ALD. For example, the inventors have discovered that adequately diffusing the precursors and/or mixing the precursors with the purge gases prior to their contact with the substrate can be important for the uniformity of the thin films.

To address the above-mentioned needs among others, a cyclic vapor deposition system according to embodiments comprises a thin film deposition chamber configured to deposit a thin film by alternatingly exposing a substrate to a plurality of precursors, wherein the thin film deposition chamber is configured to introduce one or more of the precursors into the thin film deposition chamber using a showerhead assembly configured for improved velocity and concentration uniformity of the precursors at the substrate. The showerhead assembly according to various embodiments comprises a showerhead comprising a solid body portion and a vertically oriented cavity formed therethrough at a central region thereof, wherein the showerhead is configured to deliver the precursors into the vertical cavity prior to introducing the precursors into the deposition chamber. The showerhead comprises a main inner surface, which is configured to face a substrate, that radially surrounds the vertical cavity and is tapered such that a vertical distance from the substrate to the main inner surface decreases in a radially outward direction relative a center of the substrate. The showerhead assembly additionally comprises an injector block assembly disposed over the showerhead for delivering the gases from outside of the cyclic deposition chamber into the cyclic deposition chamber through the vertical cavity. The showerhead assembly further comprises a plurality of gas channels formed in the injector block assembly and configured to flow the gases separately at least partly through the injector block assembly.

In various embodiments, the gas channels exiting the injector block assembly extend in different directions relative to each other and to a vertical axis crossing the substrate.

In various embodiments, a neck angle formed between the main surface and a horizontal plane parallel to a main surface of the substrate is 2-7 degrees.

In various embodiments, the vertical cavity has a curved sidewall having a shape of an inner lateral surface of a truncated cone.

In various embodiments, the showerhead assembly further comprises a premix chamber formed in the injector block assembly, the premix chamber configured to receive the gases separately through the gas channels and to premix the gases therein to form a gas mixture before the gas mixture is delivered to the vertical cavity.

The showerhead assembly according to various embodiments allows, among other things, improvements in velocity and concentration uniformity of the precursors arriving at the substrate surface, which in turn allows for improvements in the resulting thin film characteristics, e.g., improved thickness and composition uniformity. When the deposited thin film is a conductor, e.g., TiN, the system additionally allows for improved resistivity uniformity. The system additionally improves step coverage of the thin films in high aspect ratio structures.

In the following, embodiments may be described using specific precursors for specific films by way examples. For example, specific example precursors including TiCl₄, NH₃ and SiCl₂H₂ for depositing TiN and/or TiSiN may be used to describe the thin film deposition system and a method of depositing a thin film according to various embodiments. However, it will be understood that embodiments are not so limited, and the inventive aspects can be applied to any suitable combination of precursors for depositing any suitable thin film that can be formed using cyclic deposition processes such as ALD.

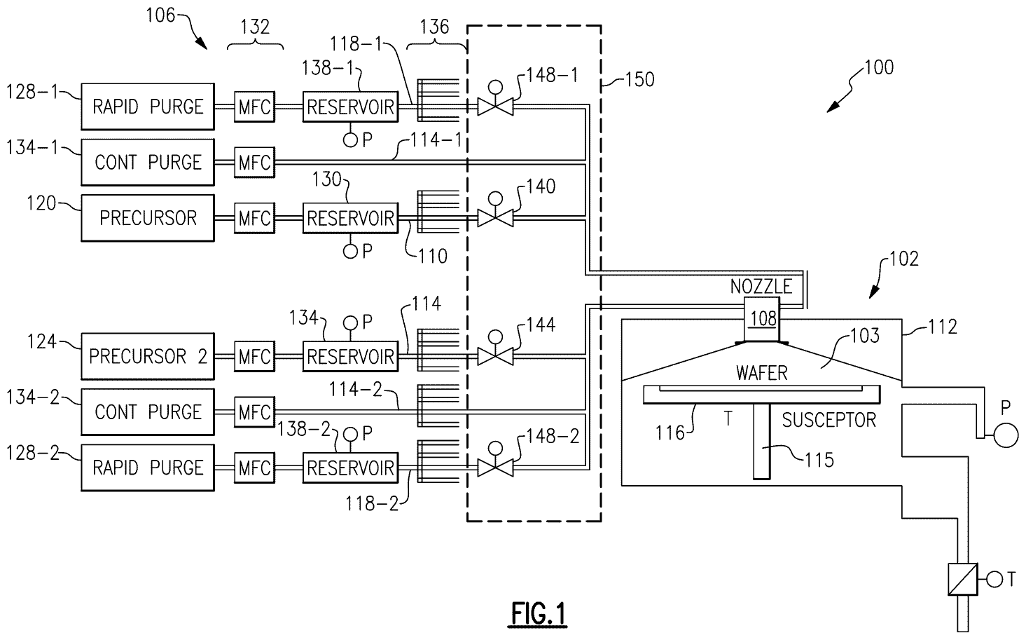

FIG. 1 schematically illustrates a thin film deposition system including a deposition chamber configured to deliver precursors using a showerhead assembly configured for improved velocity and concentration uniformity of the precursors at the substrate, according to embodiments. The thin film deposition system 100 includes a thin film deposition chamber 102 and a precursor delivery system 106 configured to deliver a plurality of precursors into the deposition chamber 102. The illustrated deposition chamber 102 is configured to process a substrate 103, e.g., a wafer, on a support 116, e.g., a susceptor, that is supported by a supporting post 115, under a process condition. The deposition chamber 102 additionally includes an injector block 108, e.g., a nozzle, configured to centrally discharge the plurality of precursors into the deposition chamber 102 through a showerhead assembly 112 configured for improved velocity and concentration uniformity of the precursors at the substrate. The injector block assembly 108 may channel the gases, e.g., a precursor and/or a purge gas, into a gas diffusing vertical cavity prior to being introduced into the deposition chamber 102 to contact the substrate 103. The showerhead assembly 112 is configured to uniformly diffuse the precursor(s) over the substrate 103 on the susceptor 116 so that a uniform deposition occurs. The deposition chamber may be equipped with pressure monitoring sensors (P) and/or temperature monitoring sensors (T).

The precursor delivery system 106 is configured to deliver a plurality of precursors from precursor sources (120, 124) and one or more purge gases, e.g., inert gases, from purge gas sources (128-1, 128-2, 134-1, 134-2) into the deposition chamber 102. Each of the precursors and purge gases is connected to the deposition chamber 102 by a respective gas delivery line. The gas delivery lines additionally include in their paths mass flow controllers (MFCs) 132 and respective precursor valves for introducing respective precursors into the thin film deposition chamber. Further advantageously, at least some of the valves can be ultrafast atomic layer deposition (ALD) valves.

For illustrative purposes only, in the illustrated configuration of FIG. 1, the plurality of precursors include a first precursor and a second precursor. The first precursor is stored in at least one first precursor source 120, and the second precursor is stored in at least one second precursor source 124. The precursor delivery system 106 is configured to deliver the first and second precursors from the first and second precursor sources 120, 124 into the deposition chamber 102 through first and second precursor delivery lines 110, 114, respectively. The first and second precursor delivery lines 110, 114 can optionally include high conductance line portions 130, 134, e.g., reservoirs, respectively. A rapid purge (RP) gas can be stored in at least two RP gas sources 128-1, 128-2. The precursor delivery system 106 is configured to deliver the rapid purge (RP) gas from the RP gas sources 128-1, 128-2 into the deposition chamber 102 through respective ones of RP gas delivery lines 118-1, 118-2. The RP gas delivery lines 118-1, 118-2 can optionally include high conductance line portions 138-1, 138-2, e.g., reservoirs, respectively. A continuous purge (CP) gas can be stored in at least two CP gas sources 134-1, 134-2. The precursor delivery system 106 is configured to deliver the CP gas from the CP gas sources 134-1, 134-2 into the deposition chamber 102 through respective ones of CP gas delivery lines 114-1, 114-2.

The first and second precursors are configured to be delivered from the first and second precursor sources 120, 124, respectively, by independently actuating first and second precursor atomic layer deposition (ALD) valves 140 and 144 that are connected in parallel to the showerhead assembly 112. Additionally, the RP purge gas is configured to be delivered from the RP purge gas sources 128-1, 128-2 by independently actuating two respective purge gas atomic layer deposition (ALD) valves 148-1, 148-2 that are connected in parallel to the showerhead assembly 112. The ALD valves 140, 144, 148-1 and 148-2 and the respective delivery lines connected to the showerhead assembly 112 can be arranged to feed the respective gases into the nozzle 108 through a multivalve block assembly 150, which may be attached to a lid of the deposition chamber 102. In the illustrated configuration, the ALD valves 140, 144, 148-1 and 148-2 are final valves before the respective gases are introduced into the deposition chamber 102.

By way of example only, the first and second precursors can include TiCl₄ and NH₃, respectively, that are delivered into the deposition chamber 102 from respective TiCl₄ and NH₃ sources through respective precursor delivery lines to form, e.g., TiN. The precursor delivery system can additionally be configured to deliver Ar as a purge gas into the process chamber from Ar sources through purge gas delivery lines. Purge gases may be delivered as a continuous purge (CP) gas, which may be delivered through precursor ALD valves, and/or as a rapid purge (RP) gas, which may be delivered through dedicated purge gas ALD valves as shown in FIG. 1. When introduced as a CP gas, the purge gas may be introduced into the deposition chamber 102 with a reactive precursor to serve as a carrier or dilution gas. The purge gas and the precursor may form a mixture within the injector block assembly 108 and/or in the vertical cavity formed through a central region of the showerhead, according to various embodiments. The illustrated precursor delivery system 100 can be configured to deliver Ar as an RP gas into the process chamber 102 from the purge gas sources 128-1, 128-2 through respective purge gas delivery lines and purge gas ALD valves 148-1, 148-2.

According to various embodiments, the thin film deposition system 100 is configured for thermal ALD without an aid of plasma. While plasma-enhanced processes such as plasma enhanced atomic layer deposition (PE-ALD) may be effective in forming conformal films on surfaces having relatively low aspect ratios, such processes may not be effective in depositing films inside vias and cavities having relative high aspect ratios. Without being limited by theory, one possible reason for this is that a plasma may not reach deeper portions of high aspect ratio vias under some circumstances. In these circumstances, different portions of the vias may be exposed to different amounts of the plasma, leading to undesirable structural effects arising from non-uniform deposition, such as thicker films being deposited near the opening of the via compared to deeper portions (sometimes called cusping or keyhole formation). For these reasons, a thermal cyclic vapor deposition such as thermal ALD may be more advantageous, because such thermal processes do not depend on the ability of the plasma to reach portions of the surface being deposited on.

Showerhead Assembly with Tapered Inner Surface and Central Vertical Diffusion Cavity for Improved Precursor Velocity and Concentration Uniformity

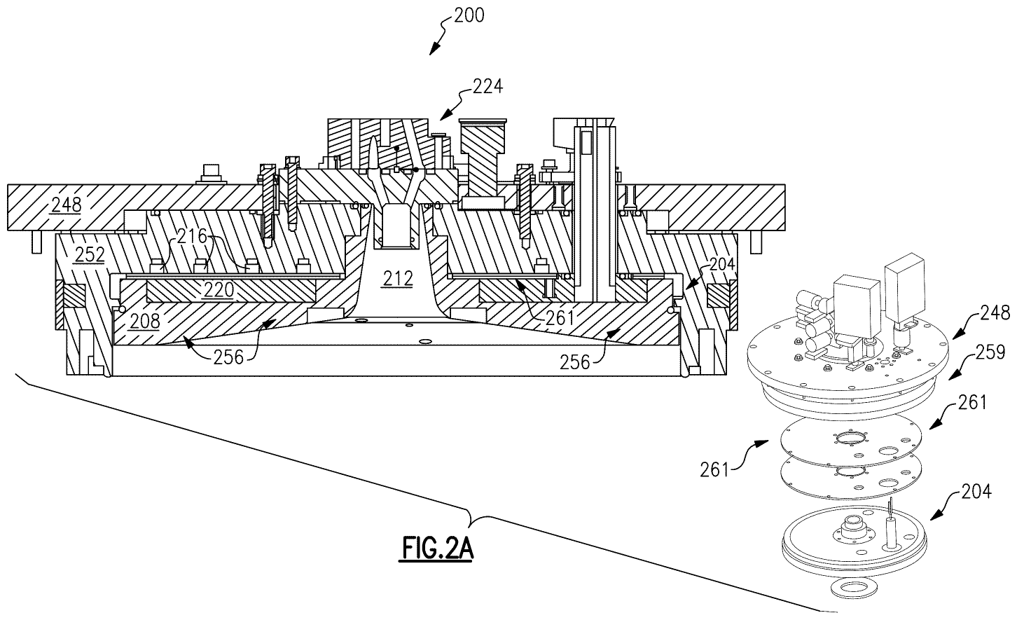

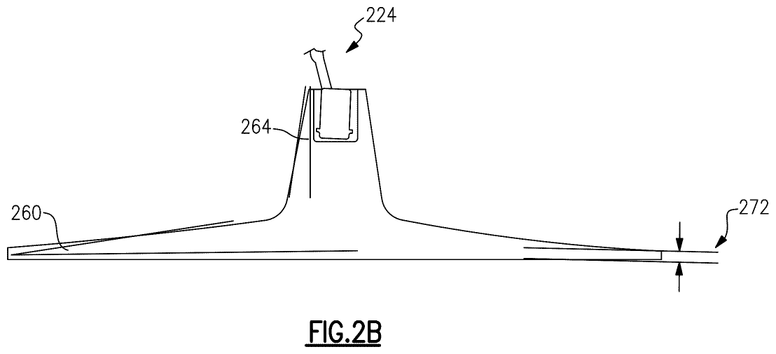

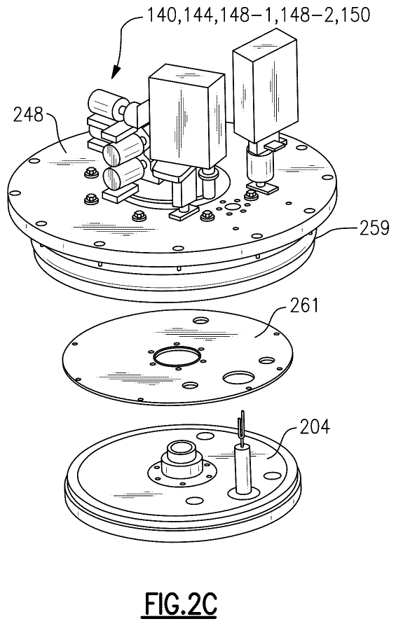

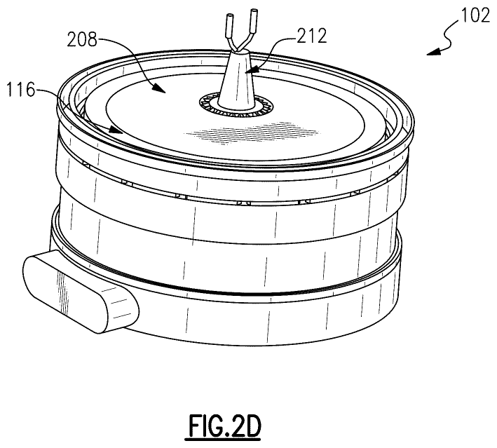

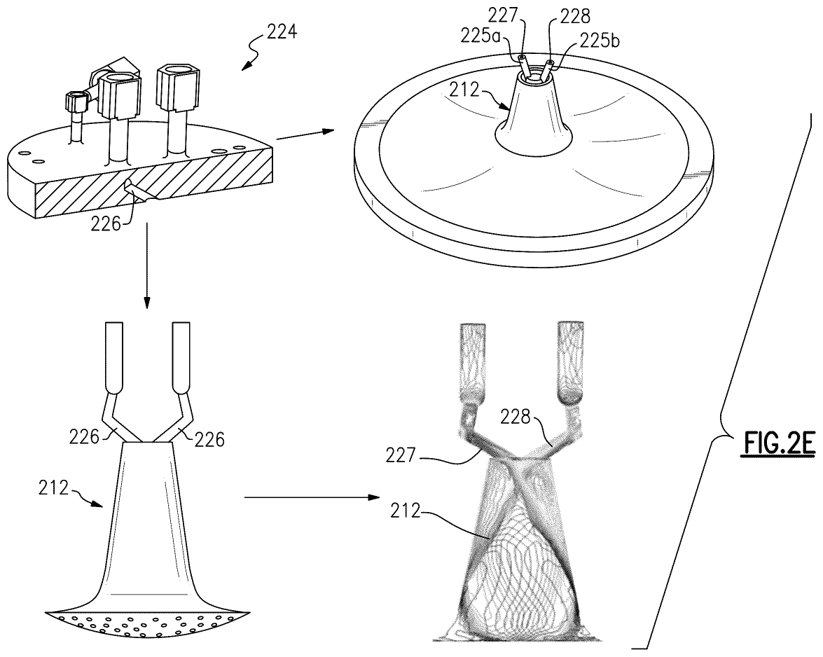

FIG. 2A illustrates a cross-sectional view of a showerhead assembly 200 tapered inner surface and a central vertical diffusion cavity, according to embodiments. The showerhead assembly 200 comprises a center-feed showerhead 204 comprising a solid body portion 208 formed of a metal and a vertical gas diffusing and/or mixing cavity 212 formed vertically therethrough at a central region thereof. The solid body portion 208 of the showerhead 204 has a main surface configured to face the substrate that has a constant slope relative a main surface of the substrate such that a thickness of the solid body portion increases towards an edge region of the solid body portion. The showerhead 204 is configured to introduce the precursors and purge gases into the thin film deposition chamber through the vertical gas diffusing cavity 212. The vertical gas diffusing cavity 212 has a curved sidewall that continuously form part of an inner surface of the showerhead 204 with the main inner surface. The vertical gas diffusing cavity extends through an entire thickness of the showerhead 204 at the central region. The showerhead assembly 200 additionally comprises a network of cooling channels 216 formed over the showerhead 204 and configured to conduct heat away from the showerhead 204. The showerhead assembly can further include a network of heating elements 220 contacting, e.g., embedded (not shown) within, the solid body portion 208 and configured to supply heat to the showerhead 204. The cooling channels 216 and the heating elements 220 can be arranged in a suitable pattern, e.g., a plurality of concentric radial rings, a serpentine pattern, etc. A filler metal volume 252 encapsulates the showerhead 204 and fills the volume between a cover plate or lid portion 248 that forms an outer cover of the showerhead assembly 200 and the showerhead 204. The filler metal volume 252 can be formed of the same metal as the solid body portion 208, e.g., aluminum.

The illustrated showerhead assembly 200 comprises the center-feed showerhead 204 having a tapered inner surface facing the substrate. The inventors have found that the tapered inner surface can be critical for improved concentration and velocity uniformity of precursors, as well as improved cycle time. Thus configured, the center-feed showerhead 204 forms tapered volume above the substrate. The inventors have found that, relative to a showerhead having a flat surface facing the substrate, the tapered volume allows for a substantial reduction of the volume above the substrate. In addition, the inventors have found that the tapered volume allows for more uniform flux of gases to be incident on the substrate surface. The reduction in volume and the uniform flux of gases in turn allows for faster cycle time in part due to shorter time that may be needed for purging the volume of unreacted precursor gases between precursor pulses. According to embodiments, the solid body portion 208 can be a continuous single piece article formed of a high conductivity metal. The inventors have discovered that the solid body portion 208 being formed of a single piece article advantageously enables rapid conduction of heat to and from the surface of the solid body portion 208. Likewise, the solid body portion 208 being formed of a high conductivity metal advantageously enables rapid conduction of heat to and from the surface of the solid body portion 208. According to various embodiments, the solid body portion is formed of an aluminum-based metal or aluminum.

The showerhead assembly 200 further comprises an injector block assembly 224 having channels formed therein for delivering gases into the gas mixing cavity 312 through one or more nozzles. The injector block assembly 224 has an upper surface configured to receive a plurality of gas lines to connect to the gas channels, and a lower surface coupled to a top opening of the vertical gas diffusing cavity 212 to flow the gases thereinto. The different ones of the plurality of gas channels are configured to flow gases or gas mixtures that are different from each other.

The nozzles may be configured to direct the respective gases substantially at an oblique angle as illustrated. The nozzles may further be configured to provide no line of sight of gas flow to the substrate or wafer. In some examples, the nozzle may be formed of an aluminum-based metal or aluminum.

A filler metal volume 252 encapsulates the showerhead 204 and fills the volume between a lid portion 248 that forms an outer cover of the showerhead assembly 200 and the showerhead 204. FIG. 2A further illustrates a thermal choke or thermal barrier 261. The thermal barrier 261 may comprise configurable inserts to modulate heat transfer from the cooling liner 259 to the showerhead 204.

As discussed above, the inventors have discovered that adequately diffusing the precursors and/or mixing the precursors with the purge gases prior to their contact with the substrate can be important for controlling the uniformity of the thin films both in thickness and physical properties including chemical composition and resistivity. Furthermore, the new discoveries have led to vast improvements including but not limited to faster responses for temperature measurement changes, improved nozzle orientation creating jetting effects and impingement on substrates, improved mixing of gases, improved thermal contact resulting in controlled temperature profiles of the showerhead, and optimized taper angles for flow and temperature uniformity. To this end, the inventors have discovered that the factors discussed below with respect to FIG. 2B can be important for enabling uniform precursor delivery, which may in turn be enabled by adequately diffusing the precursors and/or mixing the precursors with the purge gases.

FIG. 2B illustrates features for optimization of diffusion and mixing of precursors, according to embodiments. The factors include a neck angle 260, a cone angle 264, the injector block 224 configuration and the wafer-to-showerhead gap 272.

As used herein, a neck angle 260 refers to an angle between the plane of the substrate and a surface of the showerhead facing the substrate. According to various embodiments, the neck angle is less than 12°, 10°, 8°, 6°, 4° or a value in a range defined by any of these values, for instance 9.0°. Within the illustrated range of neck angles, the concentration nonuniformity showed the highest improvement at a neck angle of 5.5 degrees, while the velocity nonuniformity showed the highest improvement at a neck angle of 6.5 degrees.

As used herein, a cone angle 264 refers to an angle between a line orthogonal to a plane of the substrate and an inner surface of the mixing cavity. According to embodiments, the cone angle is less than 12°, 10°, 8°, 6° or a value in a range defined by any of these values, for instance 4.5°. The concentration and velocity nonuniformity showed a substantial improvement at a cone angle of 10 degrees relative to 11 degrees.

As used herein, a wafer-to-showerhead gap 272 refers to a distance between the bottom-most surface of the showerhead facing the substrate and an upper surface of the wafer on a susceptor. According to embodiments, the gap is less than 0.3″, 0.25″, 0.2″, 0.15″, 0.10″ or a value in a range defined by any of these values, for instance 0.15″. The inventors have found that, relative to a gap 272 of 0.25″, a gap 272 of 0.15″ and 0.10″ can reduce the volume that of gas between the showerhead and the substrate by 36% and 45%, respectively. The concentration and velocity nonuniformity showed a substantial improvement at a gap distance of 0.158″ relative to 0.258″.

The showerhead assembly 200 further comprises temperature sensors 256 in thermal communication with the showerhead 204. The inventors have discovered that the temperature sensors embedded within the solid body portion 208 formed of a high conductivity metal such as aluminum can maximize the response time of the temperature sensors 256. The inventors have found that, for closed loop temperature control with fast response time, the temperature sensors should be embedded within 0.5″, 0.3″, 0.1″ from the surface facing the substrate, or a distance in a range defined by any of these values. In some examples, temperature sensors 256 may also include a spring-loaded monitor.

In addition, the showerhead assembly 200 further comprises a network of heating elements 220 contacting, e.g., embedded (not shown) within, the solid body portion 208 and configured to supply heat to the showerhead 204.

The cooling channels 216 are configured to flow therethrough a coolant at a fixed temperature circulated by a heat exchanger, such that the surface of the solid body portion 208 adjacent the cooling channels 216 is kept at a relatively constant temperature. The coolant is kept at a temperature of 100° C., 120° C., 140° C., 160° C., 180° C., 200° C., 220° C. or a temperature in a range defined by any of these values.

The heating elements 220 are configured to supply the energy to the solid body portion 208 of the showerhead 204 through Joule heating. The heating elements 220 are configured to supply a power of 500 W, 750 W, 1000 W, 1250 W, 1500 W, 1750 W, 2000 W, or a power in a range defined by any of these values.

Using the network of heating elements 220, the network of cooling channels 216 and the temperature sensors 256, the showerhead assembly 200 is configured with a closed loop temperature control system for maintaining a relatively constant temperature at the surface during operation of the reactor chamber. Thus configured, the network of cooling channels 216 and the network of heating elements 220 formed at different vertical levels and in thermal communication with each other and with the solid body portion are such that a temperature of an inner surface of the solid body portion 208 facing a substrate is maintained at a temperature that is at least 20° C. higher than a temperature of a liquid coolant filling the cooling channels, and at a mean temperature of 160-230° C. during deposition of a thin film on the substrate at a temperature above 350° C., 400° C., 450° C., 500° C., 600° C., 650° C., or a temperature in a range defined by any of these values.

FIG. 2C illustrates a separated view of the lid portion 248, e.g., a cover plate, a thermal choke or thermal barrier 261, and the showerhead 204. The thermal barrier 261 may comprise configurable inserts to modulate heat transfer from the cooling liner 259 to the showerhead 204. The lid portion 248 has formed thereon ALD valves (140, 144, 148-1, 148-2), e.g., the multivalve block assembly 150, for controlling the flow precursors and gases into the chamber through the showerhead 204.

FIG. 2D illustrate a perspective view of the thin film deposition chamber 102 schematically illustrated in FIG. 1. The thin film deposition chamber 102 comprises the susceptor 116, e.g., a pedestal, and a solid body portion 208 of the showerhead, formed thereover. The thin film deposition chamber 102 has coupled at a central region thereof a vertical gas diffusing cavity 212. The vertical gas diffusing cavity 212 may comprise one or more inlet gases.

Some design considerations with respect to the injector block 224 are discussed below with respect to FIG. 2E. FIG. 2E illustrates an example design of the gas injector block 224 for improved diffusion and mixing of precursors, according to embodiments. In the illustrated embodiment, the injector block 224 comprises a disc or a circular slab of metal having gas channels 226 defined therein. The injector block 224 may further comprise gas channels 226, two inlet tubes 225a and 225b having inlet channels 227 and 228 formed therein, respectively, and may be coupled to the top portion of the vertical gas diffusing cavity 212. The inventors have found that the arrangement of gas channels 226 inside the injector block 224 can be an important consideration for uniform distribution of precursors and purge gases. In particular, in the illustrated example design, the gas channels 226 inside the gas injector block 224 extend in substantially off-vertical and oblique angles. This can be more clearly seen in the illustration of the gas channels without the block connected with vertical gas diffusing cavity 212. Thus configured, the gases introduced into the vertical gas diffusing cavity 212 collide at least once with the sidewalls thereof, as can be seen in the simulated distribution of gas trajectories. In one example, a computational fluid dynamics (CFD) simulation was performed, and the result is illustrated in FIG. 2E, which shows flow lines of a fluid, e.g., a precursor or purge gas, entering the top end through the inlet channels 227 and 228. As shown in the simulated flow line trajectories, the angled or slanted inlet channels 227 and 228 cause the gaseous fluid to enter the vertical gas diffusing cavity 212 from the top at an angle and collide at least once with the sidewalls of the diffusing cavity 212. This collision may cause eddies and turbulence to form in the fluid and therefore enhances mixing and diffusion and can result in more uniform precursor dispensing in the gaseous fluid when entering the deposition chamber below, e.g., as denoted by the flow lines.

A summary of improvements obtained by optimizing the features described above with respect to FIG. 2B and FIG. 2E is provided in TABLE 1 below.

TABLE 1

| | Range | | |
|---|---|---|---|
| Attribute | Simulated | Optimized | Effect |
| Neck Angle | 4.5-7° | 4.5° | 13% reduction in volume, |
| | | | improved uniformity of velocity |
| | | | and concentration |
| Cone Angle | 7-11° | <10° | Relatively little improvement in |
| | | | uniformity of velocity and |
| | | | concentration beyond 10″ |
| Wafer to | 0.25″ | <0.15″ | 36% volume reduction at 0.15″ |
| Showerhead | | | 45% volume reduction at 0.10″ |
| Gap | | | |

FIG. 2F illustrates a substrate-facing surface of a temperature-controlled showerhead assembly, according to some embodiments. The central portion of the surface corresponding to the vertical gas diffusing cavity 212 (FIG. 2A) has a plurality of perforations at a central region thereof, which serves to further diffuse the precursors and/or purge gases. At a bottom portion 215 thereof, the mixing cavity has a diameter of 20 mm, 30 mm, 40 mm, 50 mm, 60 mm, 70 mm, 80 mm, 90 mm, 100 mm, or a value in range defined by any of these values.

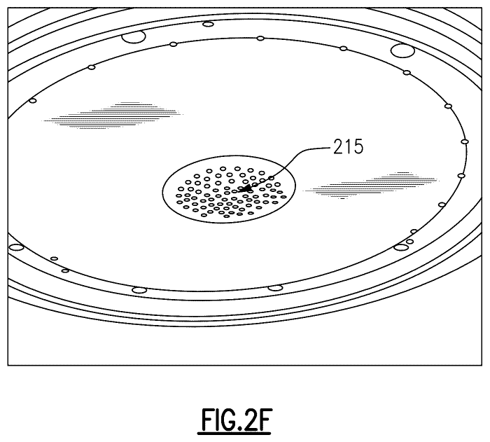

FIG. 3 shows an example deposition chamber in which various embodiments of a showerhead assembly configured for improved velocity and concentration uniformity of the precursors at the substrate can be implemented. FIG. 3 shows a perspective view of a top external portion of a deposition chamber including multiple processing stations each configured to deliver a precursor using two or more ALD valves connected in parallel to a common gas distribution plate or a showerhead assembly, according to embodiments. Each processing station is configured, e.g., in a similar manner as described above with respect to FIG. 1, and comprises a respective lid portion. Referring back to FIG. 1, after a respective one of the MFCs, each of the gas delivery lines branch off into multiple lines at a respective manifold 136. Each of the branched off lines can feed a respective gas into one of the processing stations. The illustrated process chamber 300 comprises one or more processing stations each configured to process a substrate on a support, e.g., a susceptor, under a process condition, in a similar manner as described above with respect to FIG. 1. Each processing station is configured to process a substrate under a unique process condition, including a process temperature and a process pressure. In the illustrated embodiment, there are four processing stations having corresponding lid portions 248-1, 248-2, 248-3, 248-4. The lid portions 248-1, 248-2, 248-3, 248-4 have disposed thereunder, respective ones of showerhead assemblies 350-1, 350-2, 350-3, 350-4 each configured in a similar manner as shown in FIG. 1 and FIGS. 2A-2F, the details of which are not repeated herein for brevity. The illustrated deposition chamber is thus configured to, for each processing station, introduce one or more precursors using two or more atomic layer deposition (ALD) valves each configured to supply a precursor and/or a purge gas, according to embodiments. While illustrated process chamber is a multi-station process chamber, it will be appreciated that the embodiments disclosed herein are not limited thereto, and can be implemented in any suitable single wafer or multi-wafer process chambers.

Injector Block Assemblies Having Separated Gas Channels with Improved Precursor Velocity and Concentration Uniformity

As described above, showerheads according to embodiments including a tapered inner surface and a vertical gas diffusing cavity formed at a central region thereof, with optimized neck and cone angles can greatly improve the velocity and concentration uniformity of precursors at the substrate surface by substantially reducing direct gas impingement. In molecular flow regime, the inventors have further discovered that, further improvements can be made by using an injector block assembly, where a plurality of gas channels are configured to flow the gases separately at least partly through the injector block assembly and into the vertical gas diffusion cavity through further optimization of exit channels, according to various embodiments. According to various embodiments, the gas channels exiting the injector block assembly extend in different directions relative to each other and to a vertical axis crossing the substrate. According to various embodiments, the gas channels exiting the injector block assembly extend in different directions. The different directions are angled relative to a vertical axis of the cyclic deposition chamber and do not directly cross a main surface of the substrate. Thus, under molecular flow, direct impingement of gas molecules or line-of-sight flow onto the substrate surface is substantially suppressed.

According to various embodiments, a showerhead assembly configured to deliver a plurality of gases into a cyclic deposition chamber comprises a showerhead comprising a vertical cavity formed through a central region and a main inner surface configured to face a substrate. The showerhead assembly additionally comprises an injector block assembly disposed over the showerhead for delivering the gases from outside of the cyclic deposition chamber into the cyclic deposition chamber through the vertical cavity. The showerhead assembly further comprises a plurality of gas channels formed in the injector block assembly and configured to flow the gases separately at least partly through the injector block assembly.

In some embodiments, the main inner surface radially surrounds the vertical cavity and is tapered such that a vertical distance from the substrate to the main inner surface decreases in a radially outward direction relative to a center of the substrate. In some embodiments, the gas channels exiting the injector block assembly extend in different directions relative to each other and to a vertical axis crossing the substrate. In some embodiments, a neck angle formed between the main surface and a horizontal plane parallel to a main surface of the substrate is 2-7 degrees. In some embodiments, the vertical cavity has a volume having a shape of a truncated cone, wherein the gases enter vertical cavity through a narrower top portion and exits into the cyclic deposition chamber through a base portion of the truncated cone. In some embodiments, the showerhead assembly further comprises a premix chamber formed in the injector block assembly, the premix chamber configured to receive the gases separately through the gas channels and to premix the gases therein to form a gas mixture before the gas mixture is delivered to the vertical cavity.

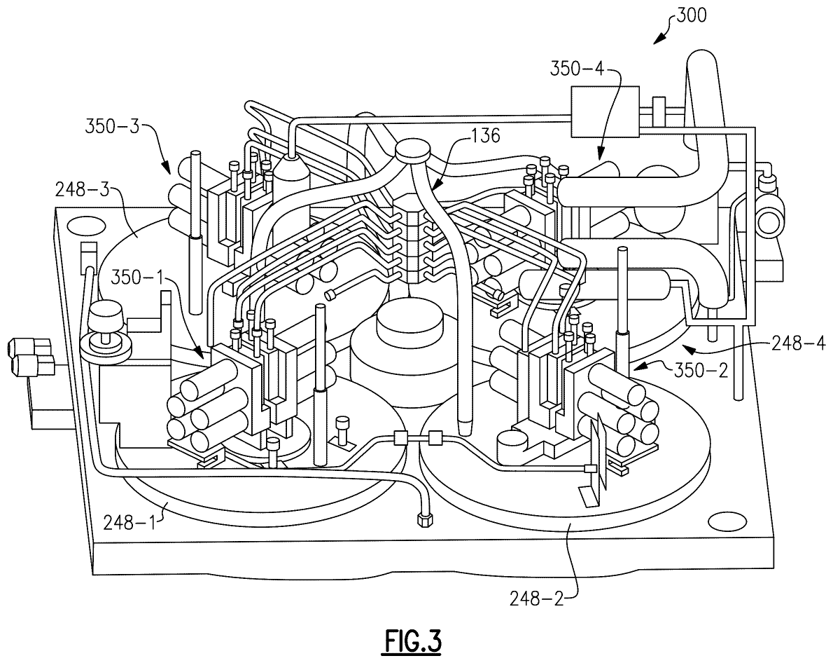

FIG. 4 shows a perspective view of an injector block assembly having formed therein a plurality of gas channels configured to flow the gases separately at least partly through the injector block assembly and subsequently into a vertical gas diffusion cavity at vertical depths thereinto, according to some embodiments. In the illustrated embodiment, similar to the injector block 224 described above with respect to FIG. 2E, the illustrated injector block assembly 424 comprises a disc or circular slab portion 428 having gas channels 426-1, 426-2 defined therein. Unlike the injector block 224, however, the injector block assembly 424 further comprises a protruding portion 430 protruding out from a bottom surface of the circular slab portion 428 and protruding into the vertical gas diffusing cavity 212. The gas channels 426-1, 426-2 extends into the protruding portion 430 before exiting from the injector block assembly 424. The circular slab portion 428 has an upper outer surface having gas channel openings configured to receive a plurality of gas lines to flow into to the gas channels 426-1, 426-2. The circular slab portion 428 has a lower outer surface having formed thereon the protruding portion 430, which is configured to couple and be inserted into to a top opening of the vertical gas diffusing cavity 212 to flow the gases thereinto.

The different ones of the plurality of gas channels 426-1, 426-2 in the injector block assembly 424 are configured to flow gases or gas mixtures that are different from each other at a given time, to be mixed after exiting into the vertical diffusing cavity 212 known as a separate flow concept. In one configuration, at a given time, one of the gas channels 426-1, 426-2 may be configured to flow a first gas or a first gas mixture including the first precursor, and the other of the gas channels 426-2 may be configured to flow a second gas or a second gas mixture including the second precursor.

By way of one example, for depositing a TiN-based material, referring back to FIG. 1, in a first deposition phase or subcycle of a deposition cycle, one of the gas channels 426-1, 426-2 may be connected to the first precursor source 120 (FIG. 1) to provide the first precursor (e.g., one of Ti and nitrogen precursor) to the substrate, or a first gas mixture including the first precursor. The first gas mixture may be a mixture of the first precursor and a carrier or dilution gas, e.g., an inert gas such as Ar or N₂. The other of the gas channels 426-1, 426-2 during the first deposition phase may optionally be connected to a continuous purge source 134-2 (FIG. 1) for flowing an inert gas such as Ar or N₂, to provide further dilution of the first precursor. Depending on the reaction and the reactants used, one or both of the carrier gas and the inert gas may be omitted in the first deposition phase. Subsequently, in a second deposition phase or subcycle of the deposition cycle, one of the gas channels 426-1, 426-2 may be connected to the second precursor source 124 (FIG. 1) to provide the second precursor (e.g., the other of Ti and nitrogen precursor) to the substrate, or a second gas mixture including the second precursor. The second gas mixture may be a mixture of the second precursor and a carrier or dilution gas, e.g., an inert gas such as Ar or N₂. The other of the gas channels 426-1, 426-2 during the second deposition phase may optionally be connected to a continuous purge source 134-2 (FIG. 1) for flowing an inert gas such as Ar or N₂, to provide further dilution of the first precursor.

It will be appreciated that, depending on the reaction and the reactants used, one or both of the carrier gas and the inert gas may be omitted in the first deposition phase. For example, precursors that are in solid or liquid form at the sources may be evaporated and carried by the carrier gas before being introduced into one of the gas channels 426-1, 426-2 during one or both of the first and second deposition phases. However, precursors that are already in gas form at the sources may be introduced into one of the gas channels 426-1, 426-2 without being mixed with a carrier gas. Still, the other of the gas channels 426-1, 426-2 during one or both of the first and second deposition phase may optionally be connected to a continuous purge source 134-2 (FIG. 1) for flowing an inert gas such as Ar or N₂, to provide further dilution of the first precursor.

Still referring to FIG. 4, in the illustrated embodiment, the gas channels 426-1, 426-2 in the injector block assembly 424 are configured such that the gases flowing through different ones of the gas channels flow separately into the vertical gas diffusing cavity 212 at different vertical depths therewithin, without mixing prior to being delivered into the vertical gas diffusing cavity 212. The illustrated injector block assembly 424 comprises the protruding portion 430 protruding vertically into the vertical gas diffusing cavity 212, and the gas channels 426-1, 426-2 extend into the protruding portion 430 before exiting at different vertical levels, such that the gases flowing in the respective gas channels remain separate through the protruding portion 430 until they exit from the protruding portion at different vertical depths into the vertical cavity.

In the illustrated embodiment, the circular slab portion 428 and the protruding portion 430 comprises a solid slab portion and a solid cylindrical portion, respectively, having defined therein the gas channels 426-1, 426-2. However, embodiments are not so limited and the circular slab portion 428 and the protruding portion 430 can have any suitable shape for extending the gas channels 426-1, 426-2 thereinto, including a suitable polygonal shape.

Each of the gas channels 426-1, 426-2 extending into the protruding portion 430 comprises a main channel that branches out into a plurality of smaller, exit channels that a corresponding gas finally passes through before entering the vertical cavity. In the illustrated embodiment, each of the main channels extend into the protruding portion 430 at an angle relative to a vertical axis before branching out into a plurality of exit channels as shown in the cross-sectional view of the protruding portion 430. In some examples, as illustrated by the cross-sectional view 450A of the lower injecting portion taken along A-A′, the exit channels can also have various directional configurations. The exit gas channels exiting the injector block assembly 424 extend in different directions crossing different sidewall portions of the vertical gas diffusing cavity 212. By way of one specific example, in the illustrated example, six exit channels are branch out from each main channel every 60 degrees. The exit channels extend outward from a main channel at a slanted angle relative to radial directions. In one example, the nozzle diameter of the exit channels may be between 0.01″ and 0.99″) or a value in range defined by any of these values, (e.g., 0.08″).

Still referring to FIG. 4, the gas channels 426-1, 426-2 are configured such that different gases exit the injector block assembly at different vertical depths of the vertical gas diffusing cavity 212. As shown, the main channels of the gas channels 426-1, 426-2 extend to different vertical levels within the protrusion portion 430 before branching out into exit channels. By way of one example, in the illustrated example, the exit channels extend outward from the main channel in horizontal directions. The exit channels extend in a horizontal direction parallel to a main surface of the substrate. As a result, the gases delivered by the gas channels 426-1, 426-2 are directed at and impinge the sidewall of the vertical gas diffusing cavity 212 at different vertical depths thereof. However, it will be appreciated that embodiments are not so limited, and in other embodiments, the main channels of the gas channels 426-1, 426-2 may extend substantially to the same vertical level such that the gases delivered by the gas channels 426-1, 426-2 are directed at and impinge the sidewall of the vertical gas diffusing cavity 212 at similar or the same vertical level.

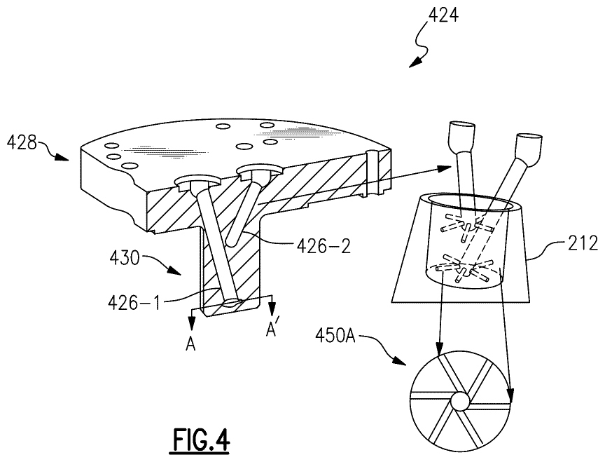

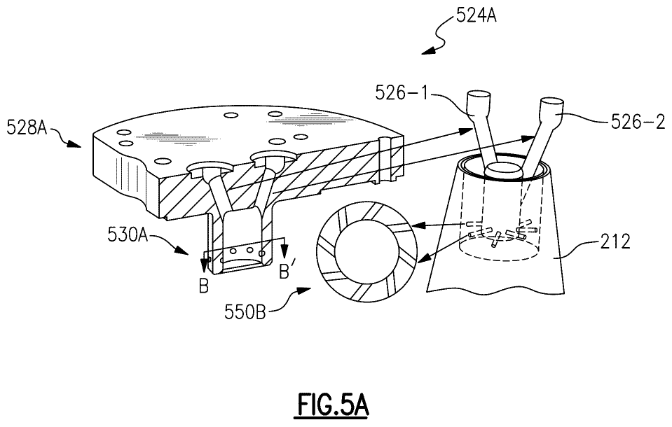

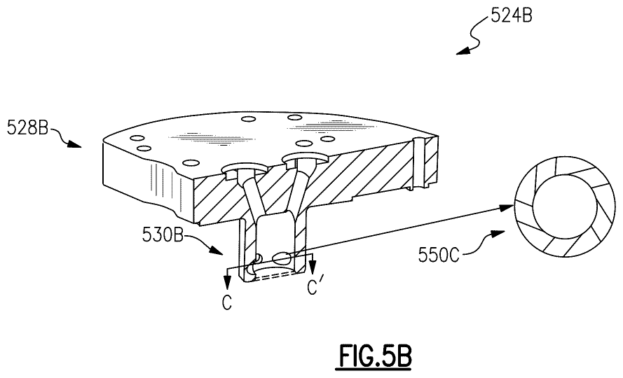

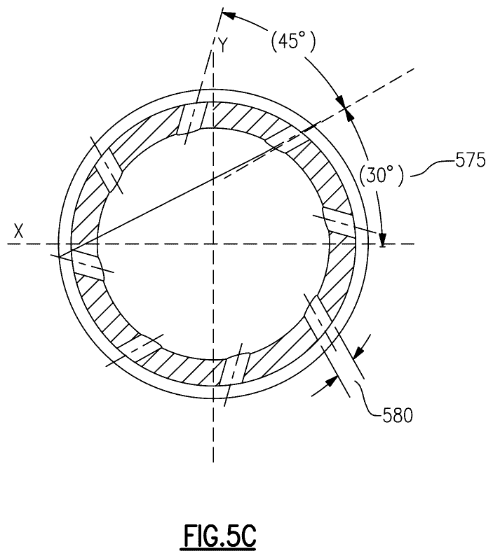

FIGS. 5A and 5B show perspective views of an injector block assembly having formed therein a plurality of gas channels configured to flow the gases separately at least partly through the injector block assembly and into a premix chamber disposed in a vertical gas diffusion cavity, according to some embodiments. In the illustrated embodiment, similar to the injector block 424 assembly described above with respect to FIG. 4, the illustrated injector block assemblies 524A, 524B comprise a disc or circular slab portion 528A, 528B having gas channels 526-1, 526-2 defined therein. Unlike the injector block assembly 424, however, the injector block assembly 524A, 524B further comprises a premix chamber 530A, 530B protruding out from a bottom surface of the circular slab portion 528A, 528B and protruding into the vertical gas diffusing cavity 212, also known as a premix with nozzles concept. The circular slab portion 528A, 528B has an upper outer surface having gas channel openings configured to receive a plurality of gas lines to flow into to the gas channels 526-1, 526-2. The circular slab portion 528A, 528B has a lower outer surface having formed thereon the premix chamber 530A, 530B, which is configured to couple and be inserted into to a top opening of the vertical gas diffusing cavity 212 to flow the gases thereinto, after premixing the gases in the premix chamber 530A, 530B.

In a similar manner as the injector block assembly 424 described above with respect to FIG. 4, the different ones of the plurality of gas channels 526-1, 526-2 in the injector block assembly 524 are configured to receive and flow gases or gas mixtures that are different from each other at a given time. The similarities between the injector block assemblies 524A, 524B and the injector block assembly 424 (FIG. 4) are not repeated herein for brevity. However, in some examples, as such in FIG. 5B, the nozzle diameter of the exit channels may be between 0.01″ and 0.99″) or a value in range defined by any of these values, (e.g., 0.2″).

Similar to the injector block assembly 424 (FIG. 4), the injector block assemblies 524A, 524B have a disc or circular slab portion 528A, 528B. Unlike the injector block assembly 424, however, the injector block assemblies 524A, 524B do not have solid protruding portions protruding from a bottom surface of the circular slab portion 528A, 528B. Instead, the circular slab portions 528A, 528B have attached at bottom surfaces thereof hollow protruding portions that serve as premix chambers 530A, 530B configured to premix gases delivered by the gas channels 526-1, 526-2 prior to being delivered into the vertical gas diffusing cavity 212. Instead of remaining separated until introduced into the vertical cavity, the gases flowing through the gas channels 526-1, 526-2 remain separated until they are introduced into the premix chambers 530A, 530B, where they are premixed before exiting therefrom into the vertical gas diffusing cavity 212 for further mixing. The premix chambers 530A, 530B comprise a top opening coupled directly to the injector block assembly for receiving the gases directly therefrom, and the gas channels 526-1, 526-2 are configured to flow the gases into the top opening of the premix chamber 530A, 530B, to be premixed therein, prior to introducing the premixed gases into the vertical gas diffusing cavity 212. After the gases flow separately through different ones of the gas channels 526-1, 526-2, the gases flow into the premix chambers 530A, 530B to be premixed therein. The gas channels 526-1, 526-1 exiting the injector block assembly extend in different directions. The illustrated premix chambers 530A, 530B comprise a hollow cavity having a shape of a cylindrical cavity that is defined by a bottom wall and a curved sidewall. The different directions of extension of the gas channels 526-1, 526-2 cross different bottom or sidewall portions of the premix chamber. As such, the molecules of different gases flowing into the premix chambers 530A, 530B have a high probability of colliding with a sidewall or a bottom surface of the premix chambers 530A, 530B before entering the vertical gas diffusing cavity 212.

Still referring to FIGS. 5A and 5B, the premix chambers 530A, 530B comprise one or more exit channels formed through the sidewall at lower portions of the premix chambers 530A, 530B. As illustrated by a cross-sectional view through the lower portion of the premix chambers 530A, 530B, the exit channels extend outward from the hollow cavity of the premix chambers 530A, 530B. The exit channels extend in a horizontal direction parallel to a main surface of the substrate and surround the mixing chamber. In the illustrated example, the exit channels are formed at the same vertical level. However, embodiments are not so limited and the exit channels can extend in directions other than horizontal directions and be formed at different vertical levels. In one example, as illustrated by the cross-sectional view 550B of the lower injecting portion taken along B-B′, the exit channels can have various directional configurations. In another example, as illustrated by the cross-sectional view 550C of the lower injecting portion taken along C-C′, the exit channels can also have various directional configurations.

FIG. 5C shows a cross sectional view of exiting gas channels formed at a lower portion of the premix chambers of the injector block assemblies illustrated in FIGS. 5A and 5B, according to some embodiments. As described above, the exit channels are directed in outward directions from the main cavity of the premix chamber 530A, 530B, in horizontal directions. As illustrated by the cross-sectional view through the lower portion of the premix chambers 530A, 530B, the exit channels extend outward from the inner cavity of the premix chambers 530A, 530B. The exit channels extend in horizontal directions parallel to a main surface of the substrate and surround the premix chamber 530A, 530B. As shown, the directions of the exit channels are not orthogonal to the inner circumference portion of the inner cavity of the premix chamber 530A, 530B. The illustrated cross-sectional view is overlaid, for illustrative purposes, a cartesian coordinate system having x and y axes.

The number of exit channels (n) can be greater than 3, 4, 5, 6, 7, 8, 9 or a value in a range defined by any of these values. The angular separation between adjacent exit channels can generally be 360°/n (e.g., equally spaced channels). The exit directions of the exit channels may not be orthogonal to tangents of the circumference of the inner cavity of the premix chamber 530A, 530B. Instead, the exit direction may form an angle relative to the directions orthogonal to the tangents. In the cross-sectional view, the directions of the exit channels form an angle, referred to in the illustration as nozzle exit angle (NEA), relative to a direction normal to a tangent of the circumference of the cylindrical cavity. The NEA 575 can be between 10° and 80°, e.g., greater than 10°, 20°, 30°, 40°, 50°, 60°, 70°, or a value in a range defined by any of these values, for instance 30°. The inventors have discovered that increasing the NEA 575 relative to a normal to the tangent of the circumference of the inner cavity wall increases the swirling velocity of the gas molecules in the vertical gas diffusing cavity 212. For example, a 30° NEA may be associated with more of an aggressive exit angle with higher swirling velocity compared to a 60° NEA. In another example, a smaller nozzle diameter 580 may be associated with higher exit and swirling velocities.

In the illustrated example, the exit channels are formed at the same vertical level. However, embodiments are not so limited and the exit channels can extend in directions other than horizontal directions and be formed at different vertical levels.

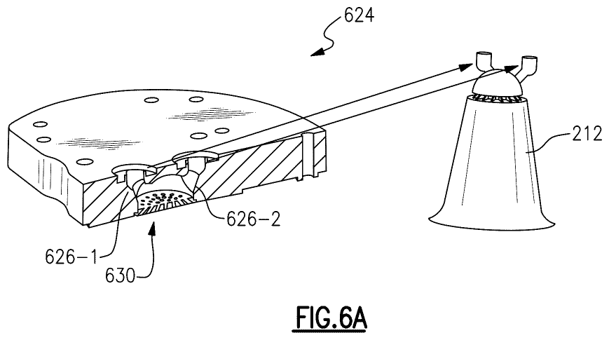

FIG. 6A shows a perspective view of an injector block assembly having formed therein a plurality of gas channels configured to flow the gases separately at least partly through the injector block assembly and into a premix chamber disposed in the injector block assembly, according to some embodiments. FIG. 6B shows perspective and cross-sectional views of the injector block assembly of FIG. 6A Including source gas lines connected thereto. In the illustrated embodiment, similar to the injector block assemblies 424, 524A and 524B described above with respect to FIGS. 4, 5A and 5B, respectively, the illustrated injector block assembly 624 comprises a disc or circular slab portion having gas channels 626-1, 626-2 defined therein. In a similar manner as the injector block assemblies 424, 524A and 524B described above with respect to FIGS. 4, 5A and 5B, respectively, the different ones of the plurality of gas channels 626-1, 626-2 in the injector block assembly 624 are configured to receive and flow gases or gas mixtures that are different from each other at a given time. The similarities between the injector block assembly 624 and the injector block assemblies 424, 524A and 524B described are not repeated herein for brevity.

Unlike the injector block assemblies 424, 524A and 524B, however, the injector block assembly 624 does not have a protruding portion or a protruding premix chamber protruding out from a bottom surface of the circular slab portion. Similarly to the injector block assemblies 524A, 524B (FIGS. 5A, 5B), the gases flowing through the gas channels 626-1, 626-2 remain separated until they are introduced into a premix chamber 630, where they are premixed before exiting therefrom into the vertical gas diffusing cavity 212. However, unlike the injector block assemblies 524A, 524B (FIGS. 5A, 5B), the premix chamber 630 does not protrude from a bottom surface of the circular slab portion. Instead, the premix chamber 630 is formed by a cavity that recesses into the circular slab portion, also known as a premix with diffuser concept. In the illustrated embodiment, the cavity has the shape of a partial dome. Further unlike the injector block assemblies 524A, 524B (FIGS. 5A, 5B), in which the gases exit through exit channels formed through the sidewall of the protruding premix chambers 530A, 530B, the gases exit the premix chamber 630 at a bottom opening thereof and into the top opening of the vertical gas diffusing cavity 212. The bottom opening may be covered by a diffusing screen comprising a plurality of perforations. Thus, instead of gas molecules being directed towards different sidewall portions of the vertical gas diffusing cavity 212, the gas molecules enter the vertical gas diffusing cavity 212 in relatively randomized directions.

FIG. 6C shows perspective and cross-sectional views of an injector block assembly having formed therein a plurality of gas channels configured to flow the gases separately at least partly through the injector block assembly and into a premix chamber disposed in the injector block assembly, according to some embodiments. In the illustrated embodiment, similar to the injector block assembly 624 described above with respect to FIGS. 6A and 6B, the illustrated injector block assembly 624B comprises a disc or circular slab portion having gas channels 626-1B, 626-2B defined therein. In a similar manner as the injector block assembly 624 described above with respect to FIGS. 6A and 6B, the different ones of the plurality of gas channels 626-1B, 626-2B in the injector block assembly 624B are configured to receive and flow gases or gas mixtures that are different from each other at a given time. The similarities between the injector block assembly 624 and the injector block assemblies 424, 524A and 524B described are not repeated herein for brevity.

Unlike the injector block assembly 624, however, the injector block assembly 624B has a protruding portion or a protruding premix chamber protruding out from a bottom surface of the circular slab portion. In addition, unlike the injector block assembly 624 in which the gases flowing through the gas channels 626-1, 626-2 remain separated until they are introduced into a premix chamber 630, in the injector block assembly 624B, the gas channels 626-1, 626-2 join in the injector block assembly 624B into a single gas channel 626B before the gases are introduced into the premix chamber 630B. Further unlike the injector block assembly 624 in which the gases exit the premix chamber 630B at a bottom opening thereof and into the top opening of the vertical gas diffusing cavity 212 through a diffusing screen comprising a plurality of perforations, in the injector block assembly 624B, the gases exit through a plurality of exit channels formed through the sidewall of the premix chamber 630B that protrudes into the vertical gas diffusing cavity 212. The cavity of the premix chamber 630 can have the shape of a partial dome, and the exit channels can be directed towards different sidewall portions of the vertical gas diffusing cavity 212.

Injector Block Assemblies Having a Combined Flow Gas Channel with Improved Precursor Velocity and Concentration Uniformity

As described above, in addition to showerhead designs according to embodiments including a tapered inner surface and a vertical gas diffusing cavity formed at a central region thereof, the inventors have further discovered that further improvements can be made by employing various optimized designs of an injector block assembly. In various embodiments of the injector block assemblies described above, the gas channels are configured to flow the gases separately at least partly through the injector block assembly, prior to the gases are introduced into the vertical gas diffusion cavity. However, embodiments are not so limited. For example, in various alternative embodiments, a consolidated gas channel is provided within the injector block assembly for combining different gases within the gas injector block assembly prior to introducing the gases into a premix chamber, followed by the vertical gas diffusing cavity.

According to various embodiments, a showerhead assembly configured to deliver a plurality of gases into a cyclic deposition chamber comprises a showerhead comprising a main inner surface configured to face a substrate, wherein the main inner surface surrounds a vertical cavity formed at a central region thereof through which the gases are delivered into the cyclic deposition chamber. The showerhead assembly additionally comprises an injector block assembly disposed over the showerhead and configured to receive the gases through external gas lines connected thereto and to deliver the gases into the cyclic deposition chamber through the vertical cavity. The showerhead assembly further comprises a premix chamber formed in the injector block assembly, where the premix chamber is configured to premix the gases received from the gas lines to form a gas mixture therein before the gas mixture is delivered to the vertical cavity.

In some embodiments, the main inner surface radially surrounds the vertical cavity and is tapered such that a vertical distance from the substrate to the main inner surface decreases in a radially outward direction relative to a center of the substrate. In some embodiments, an internal volume of the premix chamber has a constricted portion that constricts the gas mixture prior to delivering the gas mixture to the vertical cavity. In some embodiments, the premix chamber has a lower portion comprising a plurality of nozzles for injecting the gas mixture into the vertical cavity. In some embodiments, a neck angle formed between the main surface and a horizontal plane parallel to a main surface of the substrate is 2-7 degrees. In some embodiments, the vertical cavity has a volume having a shape of a truncated cone, wherein the gases enter vertical cavity through a narrower top portion and exits into the cyclic deposition chamber through a base portion of the truncated cone.

FIG. 7 illustrates top and bottom perspective views of an injector block assembly having formed therein a premix chamber configured to premix the gases received from the gas lines to form a gas mixture before the gas mixture is delivered to the vertical cavity, according to some embodiments. In the illustrated embodiment, similar to the injector block assembly 624B described above with respect to FIG. 6C, the illustrated injector block assembly 724 comprises a disc or circular slab portion and a protruding portion protruding out from a bottom surface of the circular slab portion and into the vertical cavity. The similarities between the injector block assembly 724 and the injector block assemblies described above including the injector block assemblies 424, 524A, 524B, 624 and 624B are not repeated herein for brevity.

However, unlike the injector block assemblies described above including the injector block assembly 424, 524A, 524B, 624 and 624B, in which the gases flowing through the gas channels remain separated at least partly within the injector block assembly, in the illustrated injector block assembly 724, the gases from the external gas lines flow directly into a premix chamber 730 without flowing separately therethrough. The premix chamber 730 has multiple portions, including an upper receiving portion 726, a constricted middle portion 728, and a lower injecting portion 732. As shown in the semi-transparent view of the vertical gas diffusing cavity 212 (far right), the lower injecting portion 732 is partly inserted into the vertical diffusing cavity 212. The constricted middle portion 728 is substantially narrower in width or diameter compared to the upper receiving portion 726 or the lower injection portion 732. As configured, the premix chamber has an hourglass shape. The gases initially enter from external gas lines into the upper receiving portion 726, where the gases form an initial mixture prior to passing through the constricted portion 728. After passing through the constricted portion 728, the gas mixture flows into the lower injecting portion 732, before exiting into the top opening of the vertical gas diffusing cavity 212 through a plurality of exit channels formed through the sidewall of the lower injecting portion 732. Similar to the injector block assembly 624B (FIG. 6C), a portion of the premix chamber 730 including the lower injecting portion 732 protrudes into the vertical gas diffusing cavity 212. The cavity of the lower injecting portion 732 can have the shape of a partial dome, and the exit channels can be directed towards different sidewall portions of the vertical gas diffusing cavity 212. As illustrated by the cross-sectional view 750C of a cross section of the lower injecting portion 732 taken along D-D′, the exit channels can have various directional configurations as described above with respect to FIG. 5C.

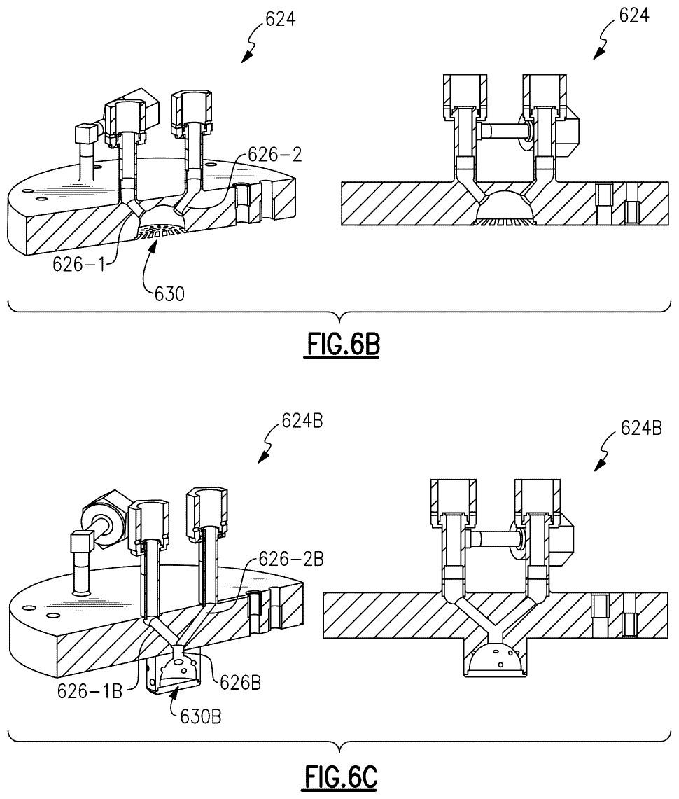

FIG. 8 illustrates top and bottom perspective views of an injector block assembly having formed therein a premix chamber configured to premix the gases received from the gas lines to form a gas mixture before the gas mixture is delivered to the vertical cavity, according to some other embodiments. In the illustrated embodiment, similar to the injector block assembly 724 described above with respect to FIG. 7, the injector block assembly 824 comprises a disc or circular slab portion and a protruding portion protruding out from a bottom surface of the circular slab portion and into the vertical cavity. The similarities between the injector block assembly 824 and the injector block assembly 724 (FIG. 7) are not repeated herein for brevity.

Similar to the injector block assembly 724, in the illustrated injector block assembly 824, the gases from the external gas lines flow directly into a premix chamber 830 without flowing separately therethrough. Further similar to the injector block assembly 724, the premix chamber 830 has multiple portions, including an upper receiving portion 826 and a constricted portion 828. However, unlike the injector block assembly 724 of FIG. 7, the premix chamber 830 does not include a wider lower injecting portion 732. Instead, the lower injector portion 832 of the premix chamber 830 has substantially the same diameter or width as the constricted portion 828. After passing through the constricted portion 828, the gas mixture flows into the lower injecting portion 832, before exiting into the top opening of the vertical gas diffusing cavity 212 through a plurality of exit channels formed through the sidewall of the lower injecting portion 832. The exit channels can be directed towards different sidewall portions of the vertical gas diffusing cavity 212. As illustrated by the cross-sectional view 850C of a cross section of the lower injecting portion 832 taken along E-E′, the exit channels can have various directional configurations as described above with respect to FIG. 5C. As shown by the schematic views 850D and 850E the exit channels can be directed substantially horizontally (e.g., parallel to a substrate major surface) or at an angle relative to the horizontal direction.

Showerhead Assembly with Diffuser Plate for Further Improved Precursor Velocity and Concentration Uniformity

In various embodiments, the showerhead assembly according to embodiments substantially enhance the precursor velocity and concentration uniformity by flowing gases from the vertical cavity to the substrate without an intervening structure between the showerhead and the substrate. In various other embodiments, the precursor velocity and concentration uniformity can further be enhanced by including a diffuser plate between the inner surface of the showerhead and the substrate. The diffuser can have the effect of further randomizing the flux of gas molecules.

Accordingly, according to embodiments, a showerhead assembly configured to deliver a plurality of gases into a cyclic deposition chamber comprises a showerhead comprising a main inner surface configured to face a substrate, wherein the main inner surface surrounds a vertical cavity formed at a central region thereof through which the gases are delivered into the cyclic deposition chamber. The showerhead assembly additionally comprises an injector block assembly disposed over the showerhead and configured to receive the gases through external gas lines connected thereto and having a plurality of injection nozzles for delivering the gases into the cyclic deposition chamber through the vertical cavity. The showerhead assembly further comprises a diffuser plate substantially overlapping a lateral footprint of the showerhead and disposed vertically between the showerhead and the substrate, the diffuser plate comprising a plurality of holes for diffusing the gases received from the vertical cavity prior to the gases reaching the substrate.

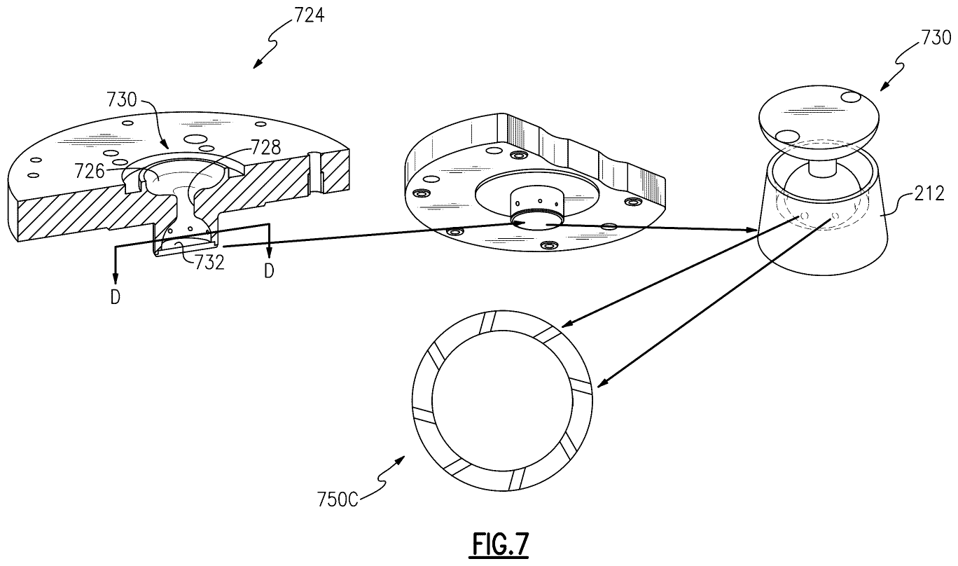

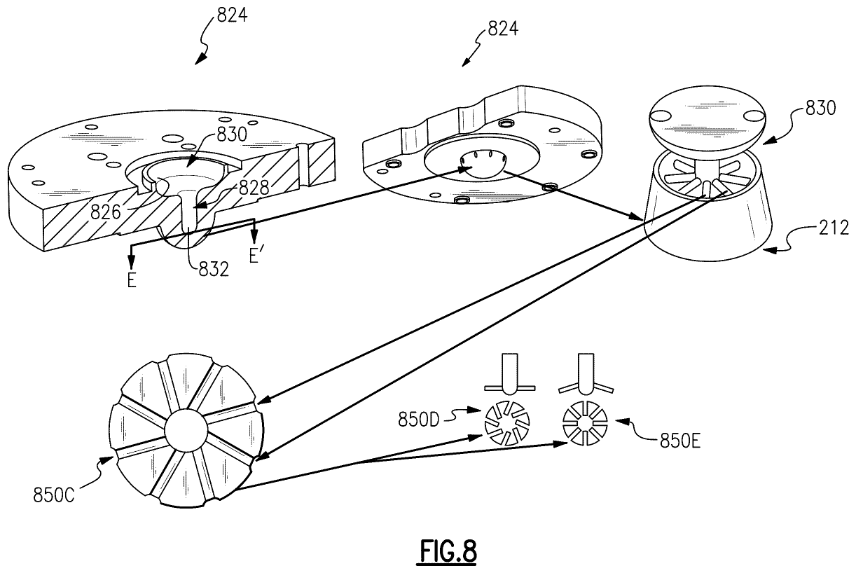

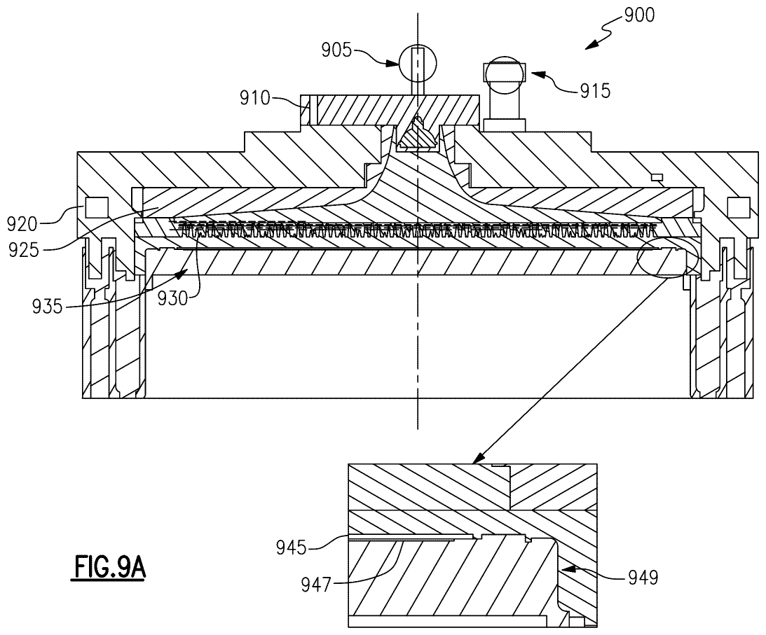

FIG. 9A illustrates a side view of the thin film deposition chamber including a showerhead assembly having a diffuser plate, according to some embodiments. Various features of the showerhead assembly are in accordance with various embodiments disclosed elsewhere herein. However, unlike other embodiments disclosed herein, the illustrated thin film deposition chamber 900 includes a diffuser plate between the main inner surface of the showerhead and the substrate.

In one example, the thin film deposition chamber 900 may comprise a gas inlet 905, a gas nozzle 910, a coolant inlet 915, a lid liner 920, a cone showerhead 925, a diffuser plate 930, a heater and liner assembly 935, a substrate or wafer 945, an under-wafer fluid 947, and a susceptor 949.

FIG. 9B illustrates a major surface of the diffuser plate having a plurality of holes formed therein for diffusing gases. FIG. 9C illustrates a side view of the diffuser plate 930 shown in FIG. 9B. In the illustrated embodiments, the holes 975 of the diffuser plate 930 substantially cover an entire area of the diffuser plate. For example, the holes 975 of the diffuser plate 930 laterally overlap the central region of the main inner surface while being omitted from an outermost region of the diffuser plate having formed therethrough screw holes. According to various embodiments, the outer band in which holes are not present can correspond to outer 5%, 10%, 15%, 20%, 25%, 30%, or any value in a range defined by these values, of the radius of the diffuser plate.

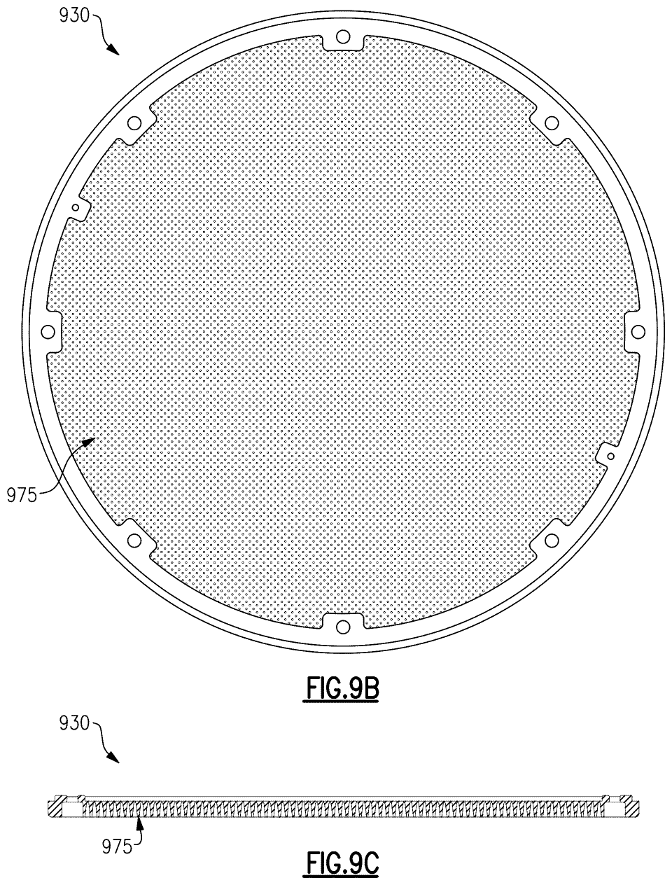

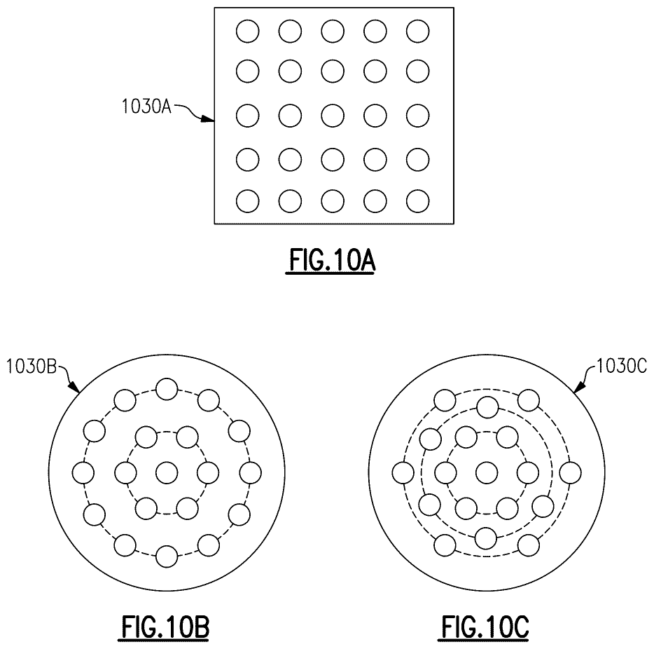

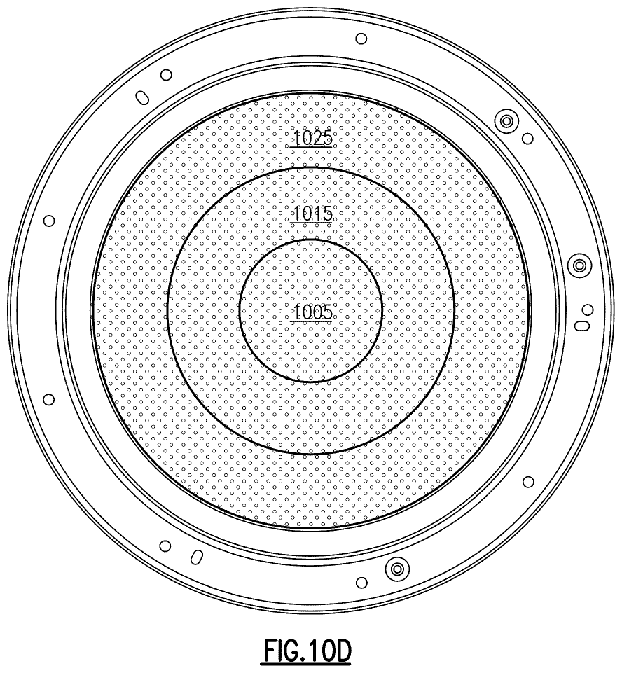

The pattern of holes in the diffuser plates can be optimized for particular flow patterns. For example, in some embodiments, the holes form a random pattern. In some other patterns, the holes can have a regular pattern. Without limitation, FIGS. 10A-10C schematically illustrate different example patterns of holes that can be implemented in the diffuser plate illustrated in FIGS. 9B and 9C. The regular pattern can include a substantially constant distance between adjacent holes or adjacent groups of holes.

Referring to FIG. 10A, a portion 1030A of a diffuser plate shows a regular pattern of holes that include a rectangular array. The rectangular array includes rows having a substantially constant inter-row distance and columns having a substantially constant inter-column distance.

Referring to FIGS. 10B and 10C, a portion 1030B of a diffuser plate and a portion 1030C of a diffuser plate, show regular patterns that include a circular array including a plurality of rings each having a plurality of holes at a constant radius. In the portion 1030B of the diffuser plate shown in FIG. 10B, the holes of adjacent ones of the rings lie on a common radial line extending outward from a center of the diffuser plate. In addition, the angular separation between adjacent holes within a given ring can be substantially constant. In contrast, in the portion 1030C of the diffuser plate shown in FIG. 10C, the holes of adjacent ones of the rings do not lie on a common radial line extending outward from a center of the diffuser plate. In addition, the angular separation between adjacent holes within a given ring can be substantially different.

FIG. 10D illustrates a major surface of the diffuser plate having a plurality of concentric radial zones, wherein different radial zones have differently arranged holes. In some implementations, one of both of the hole pattern or hole size can be different in different zones. In some other implementations, one or both of the area density and the size of the holes increase with increasing distance from a central axis of the showerhead. In the illustrated diffuser plate, the hole density and pattern are generally similar for different zones, but the hole size increases from center to edge. In one example, the diffuser plate may include three different zones, Zone 1 1005, Zone 2 1015, and Zone 3 1025, where each zone may have similar hole densities and patterns, but the hole sizes increase from Zone 1 to Zone 3.

Showerhead Assembly with Blocking Plate for Further Improved Precursor Velocity and Concentration Uniformity

In various embodiments, the showerhead assembly according to embodiments substantially enhance the precursor velocity and concentration uniformity by flowing gases from the vertical cavity to the substrate without an intervening structure between the showerhead and the substrate. In various other embodiments, the precursor velocity and concentration uniformity can further be enhanced by including a blocking plate between the inner surface of the showerhead and the substrate. The blocking plate can have the effect of, among other effects, diverting some of the flux that would otherwise impinge at a central area of the substrate.

Accordingly, according to embodiments, a showerhead assembly configured to deliver a plurality of gases into a cyclic deposition chamber comprises a showerhead comprising a main inner surface configured to face a substrate, wherein the main inner surface surrounds a vertical cavity formed at a central region thereof through which the gases are delivered into the cyclic deposition chamber. The showerhead assembly additionally comprises an injector block assembly disposed over the showerhead and configured to receive the gases through external gas lines connected thereto and having a plurality of injection nozzles for delivering the gases into the cyclic deposition chamber through the vertical cavity. The showerhead assembly further comprises a blocking plate disposed laterally at the central region and vertically between the injection nozzles and the substrate.

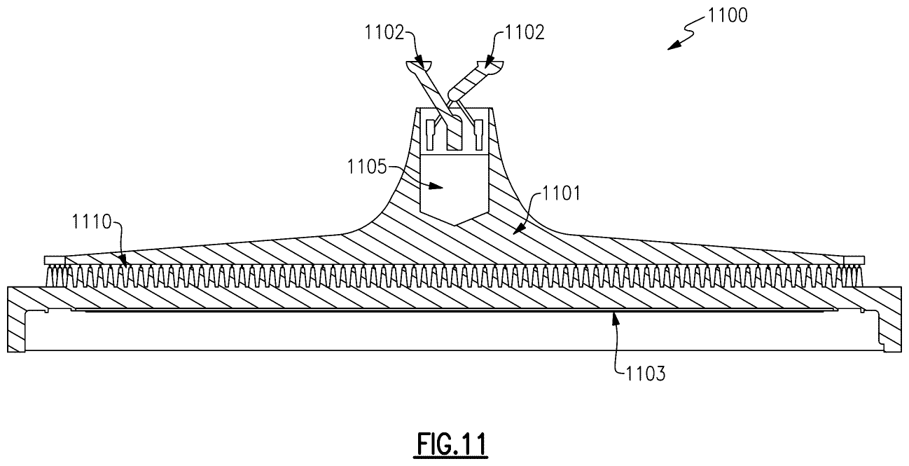

FIG. 11 illustrates a side view of the thin film deposition chamber including a showerhead assembly having a diffuser plate and a blocking plate, according to some embodiments. The illustrated thin film deposition chamber 1100 includes the showerhead assembly 1101, e.g., a shaped gas volume cone showerhead, a substrate or wafer 1103, the blocking plate 1105, e.g., a flow equalizer, vertically disposed between the injection nozzles 1102 and the diffuser plate 1110 and laterally disposed below the injection nozzles 1102. In the illustrated embodiment, the blocking plate 1105 has a lateral dimension that is smaller than a smallest lateral dimension of the vertical cavity such that the blocking plate can be at least partially vertically inserted into the vertical cavity.

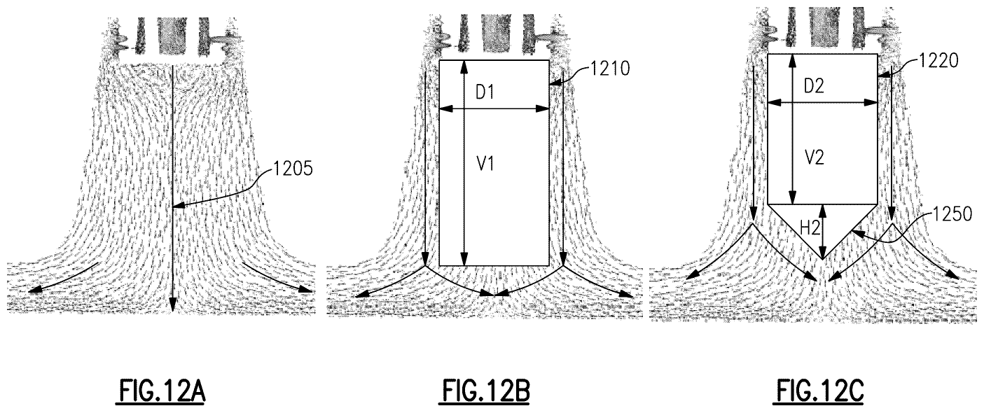

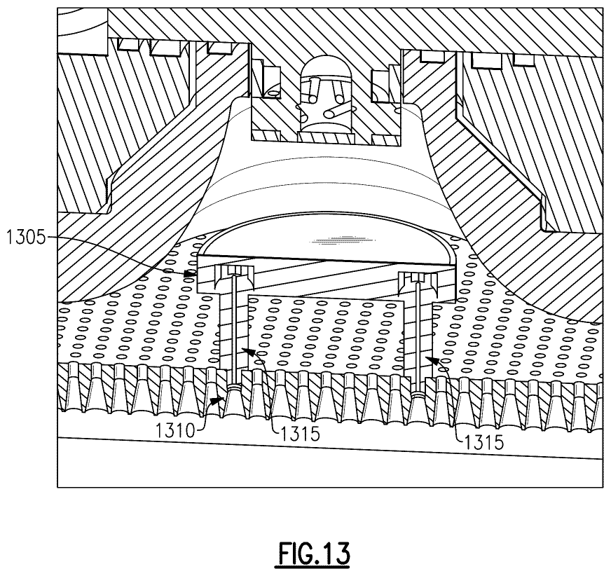

FIG. 12A illustrates a flow pattern diagram of gases through a vertical cavity of a showerhead without a blocking plate. As shown, without the blocking plate, the velocity and concentration of gases may be the highest near the center region 1205 of the substrate, e.g., a no flow equalizer. To mitigate, FIG. 12B illustrates a flow pattern diagram of gases through a vertical cavity of a showerhead having a vertically elongated blocking plate 1210, according to some embodiments. The illustrated blocking plate 1210 comprises a cylindrical portion having a vertical length V1 (a reasonable length in millimeters), e.g., 1 mm to 100 mm, extending in a vertical direction substantially greater than a diameter D1 (a reasonable length in millimeters), e.g., 1 mm to 100 mm, thereof (e.g., V1: 40 mm, D1: 24 mm), also denoted as flow equalizer A. FIG. 12C illustrates a flow pattern diagram of gases through a vertical cavity of a showerhead having a vertically elongated blocking plate 1220, according to some other embodiments. Similar to the blocking plate illustrated in FIG. 12B, the illustrated blocking plate comprises a cylindrical portion having a vertical length V2 (a reasonable length in millimeters), e.g., 1 mm to 100 mm, extending in a vertical direction substantially greater than a diameter D2 (a reasonable length in millimeters), e.g., 1 mm to 100 mm, thereof (e.g., V2: 30 mm, D2: 24 mm). However, unlike the blocking plate illustrated in FIG. 12B, the blocking plate illustrated in FIG. 12C has a tip portion 1250 with a height H2 (a reasonable length in millimeters), e.g., 1 mm to 100 mm, that is sharpened towards the substrate (e.g., H2: 10 mm), also denoted as flow equalizer B.

FIG. 13 illustrates a cross-sectional side view of the thin film deposition chamber including a showerhead assembly having a diffuser plate having mounted thereon a blocking plate, according to some other embodiments. Unlike the blocking plates illustrated in FIGS. 12B and 12C, the illustrated blocking plate comprises a cylindrical portion having a vertical length extending in a vertical direction that is substantially smaller than a diameter of the blocking plate. The blocking plate 1305 is attached to the diffuser plate 1310 by a plurality of anchors 1315 to suspend.

Showerhead Assembly with Nonlinearly Varying Gap Between Showerhead Main Surface and Substrate

As described above, one of the advantages of various showerhead assemblies disclosed herein arises from substantially reduced free volume between the showerhead and the substrate. Such reduction in volume results in, among other things, faster throughput due to shorter time to pump out gases between different exposures.

Accordingly according to embodiments, a showerhead assembly configured to deliver a plurality of gases into a cyclic deposition chamber comprises a showerhead comprising a main inner surface configured to face a substrate, wherein the main inner surface surrounds a vertical cavity formed at a central region thereof through which the gases are delivered into the cyclic deposition chamber. The showerhead assembly additionally comprises an injector block assembly disposed over the showerhead and configured to receive the gases through external gas lines connected thereto and having a plurality of injection nozzles for delivering the gases into the cyclic deposition chamber through the vertical cavity. The main inner surface of the showerhead forms an angle, with respect to a main surface of the substrate, that is different at different radial distances from a central axis of the showerhead. A vertical gap between the main inner surface of the showerhead and a main surface of the substrate changes nonlinearly with radial distance from a central axis of the showerhead.

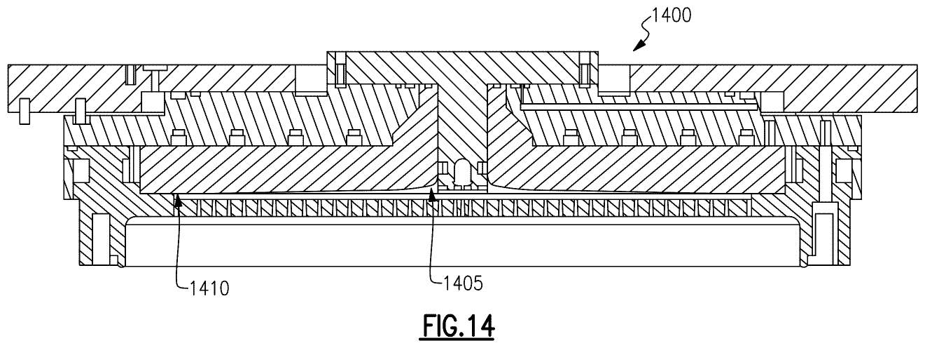

FIG. 14 illustrates a side view of the thin film deposition chamber including a showerhead assembly having a main inner surface having an angle, with respect to a main surface of the substrate, that is different at different radial distances from a central axis of the showerhead, according to embodiments. In some embodiments, the thin film deposition chamber 1400 includes the main inner surface 1405 having the angle 1410 that can have multiple values. In some other embodiments, the angle can vary continuously. In the illustrated embodiment, the main inner surface of the showerhead forms the angle, with respect to the main surface of the substrate, that decreases in the radial direction from the central axis of the showerhead.

In some embodiments, the varying angles between a main inner surface of the showerhead and the substrate can have a value in a range described above with respect to the neck angle, e.g., less than 12°, 10°, 8°, 6°, 4° or a value in a range defined by any of these values. In some embodiments, these values can represent the highest angle, e.g., towards the center of the main surface. The outer angles can have lower values. In some embodiments, at least an outer portion of the main surface can be at 0° angle; i.e., at least an outer portion of the main surface can be substantially parallel to the substrate surface.

### Applications

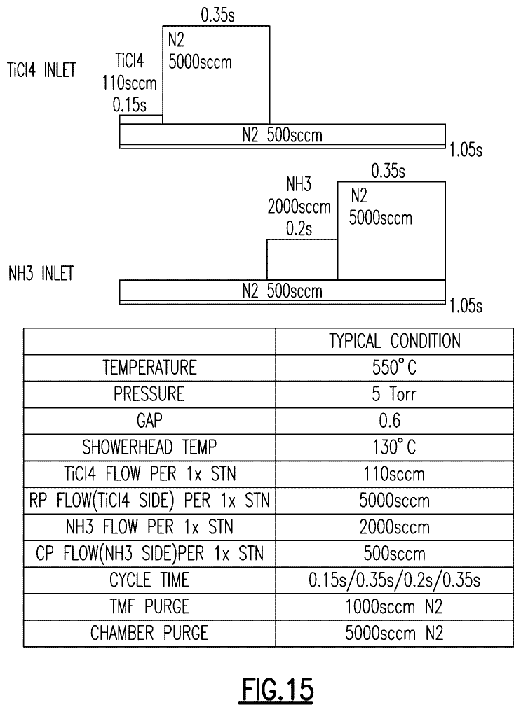

FIG. 15 illustrates, by way of example only, an example precursor delivery sequence for delivering one or more precursors using a temperature-controlled showerhead assembly, according to some embodiments. A first and second precursor inlets are connected to first and second precursor delivery lines arranged as described above, e.g., with respect to FIG. 1. An ALD cycle comprises a first subcycle for exposing a substrate to the first precursor, and a second subcycle for exposing the substrate to the second precursor. As described above, each of the precursor ALD valves is a three-port valve, and in some implementations, a continuous purge (CP) gas, e.g., an inert gas, may be flown through the ALD valves while the substrate is exposed to the first precursor and/or the second precursor. When introduced simultaneously into the reactor, the CP gas and a precursor are mixed in the vertical gas diffusing cavity (e.g., 212 in FIG. 2A) prior to being introduced into the main reactor. In the illustrated embodiment, each of the first and second subcycles further comprises a rapid purge (RP) by an inert gas following the exposure to one or both of the first and second precursors, respectively. The rapid purge may be performed using a purge ALD valve as described above. The rapid purge is higher in magnitude than the continuous purge.

The deposition systems according to embodiments are particularly advantageous for forming the thin film on a substrate that comprises high aspect ratio structures having an opening width less than 1 micron, 500 nm, 200 nm, 100 nm, 50 nm, 20 nm or a value in a range defined by any of these values, an aspect ratio exceeding 5, 10, 20, 50, 100, 200 or a value in a range defined by any of these values, and an area density such that the surface area is greater than a that of a planar substrate as described above. Substrates having such topography may be conformally coated with thin films comprising TIN, TiSiN and/or TiAlN according to embodiments with a step coverage as defined above that exceeds 50%, 60%, 70%, 80%, 90%, 95%, or has a value in a range defined by any of these values or higher.

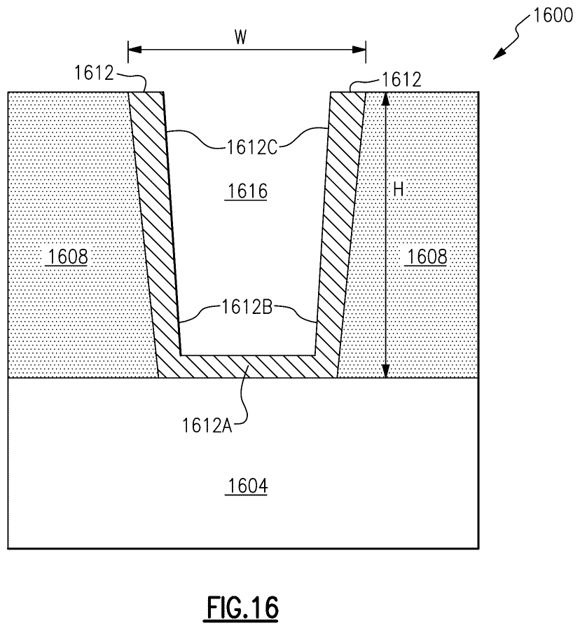

One measure of conformality in the context of high aspect ratio structures for which high uniformity is referred to herein as step coverage. A high aspect ratio structure may be, e.g., a via, a hole, a trench, a cavity or a similar structure. By way of an illustrative example, FIG. 16 schematically illustrates a semiconductor structure 1600 having an example high aspect ratio structure 1616 formed therein, to illustrate some example metrics of defining and/or measuring conformality of thin films formed on high aspect ratio structures. The illustrated high aspect ratio structure 1616 is lined with a thin film 1612, e.g., TiN layer deposited according to embodiments, having different thicknesses at different portions thereof. As described herein, a high aspect ratio structure has an aspect ratio, e.g., a ratio defined as a depth or height (H) divided by a width (W) at the opening region of the high aspect ratio structure 1616, that exceeds 1. In the illustrated example, the high aspect ratio structure 1616 is a via formed through a dielectric layer 1608, e.g., an intermetal dielectric (ILD) layer, formed on a semiconductor substrate 1604, such that a bottom surface of the high aspect ratio structure 1616 exposes the underlying semiconductor substrate 1604. The thin film 1612 can coat different surfaces of the high aspect ratio structure 1616 with different thicknesses. As described herein, one metric for defining or measuring the conformality of a thin film formed in a high aspect ratio is referred to as step coverage. A step coverage may be defined as a ratio between a thickness of a thin film at a lower or bottom region of a high aspect ratio structure and a thickness of the thin film at an upper or top region of the high aspect ratio structure. The upper or top region may be a region of the high aspect ratio structure at a relatively small depth at, e.g., 0-10% or 0-25% of the H measured from the top of the opening. The lower or bottom region may be a region of the high aspect ratio structure at a relatively high depth at, e.g., 90-100% or 75-100% of the H measured from the top of the opening. In some high aspect ratio structures, a step coverage may be defined or measured by a ratio of thicknesses of the thin film 1612A formed at a bottom surface to the thin film 1612C formed at upper or top sidewall surfaces of the high aspect ratio structure. However, it will be appreciated that some high aspect ratio structures may not have a well-defined bottom surface or a bottom surface having small radius of curvature. In these structures, a step coverage may be more consistently defined or measured by a ratio of thicknesses of the thin film 1612B formed at a lower or bottom sidewall surface to the thin film 1612C formed at an upper or top sidewall surfaces of the high aspect ratio structure.

The deposition systems according to embodiments, at least in part due to the relatively constant temperature uniformity of the showerhead and effective diffusion and/or missing of the precursors with the purge gases, gives rise to substantial improvement in step coverage in high aspect ratio structures. By employing the temperature-controlled showerhead assembly according to embodiments, high aspect ratio structures having an aspect ratio exceeding 1, 2, 5, 10, 20, 50, 100, 200 or a value in a range defined by any of these values may be conformally coated with a thin film such as a TiN film according to embodiments with a step coverage as defined herein that exceeds 70%, 80%, 90%, 95%, or has a value in a range defined by any of these values. Thus, obtained step coverage values represent an improvement over corresponding step coverage values obtained using a comparable thin film deposition system having gas delivery lines without the high conductance line portions by 5%, 10%, 15%, 20% or a value in a range defined by any of these values.

### Additional Embodiments

Additional embodiments of the showerhead assemblies are disclosed below under the headings EXAMPLE EMBODIMENTS I-III.

### Example Embodiments I

1. A showerhead assembly configured to deliver a plurality of gases into a cyclic deposition chamber, the showerhead assembly comprising:
   a showerhead comprising a vertical cavity formed through a central region and a main inner surface configured to face a substrate, wherein the main inner surface radially surrounds the vertical cavity;
   an injector block assembly disposed over the showerhead for delivering the gases from outside of the cyclic deposition chamber into the cyclic deposition chamber through the vertical cavity; and
   a plurality of gas channels formed in the injector block assembly and configured to flow the gases separately at least partly through the injector block assembly, wherein the gas channels exiting the injector block assembly extend in different directions relative to each other and to a vertical axis crossing the substrate.
2. A showerhead assembly configured to deliver a plurality of gases into a cyclic deposition chamber, the showerhead assembly comprising:
   a showerhead comprising a vertical cavity formed through a central region and a main inner surface configured to face a substrate,
   wherein the main inner surface radially surrounds the vertical cavity and is tapered such that a vertical distance from the substrate to the main inner surface decreases in a radially outward direction relative a center of the substrate;
   an injector block assembly disposed over the showerhead for delivering the gases from outside of the cyclic deposition chamber into the cyclic deposition chamber through the vertical cavity; and
   a plurality of gas channels formed in the injector block assembly configured to flow the gases separately at least partly through the injector block assembly,
   wherein a neck angle formed between the main surface and a horizontal plane parallel to a main surface of the substrate is 2-7 degrees.
3. A showerhead assembly configured to deliver a plurality of gases into a cyclic deposition chamber, the showerhead assembly comprising:
   a showerhead comprising a vertical cavity formed through a central region and a main inner surface configured to face a substrate, wherein the main inner surface radially surrounds the vertical cavity;
   an injector block assembly disposed over the showerhead for delivering the gases from outside of the cyclic deposition chamber into the cyclic deposition chamber through the vertical cavity; and
   a plurality of gas channels formed in the injector block assembly configured to flow the gases separately at least partly through the injector block assembly,
   wherein the vertical cavity has a volume having a shape of a truncated cone, wherein the gases enter the vertical cavity through a narrower top portion and exits into the cyclic deposition chamber through a base portion of the truncated cone wider than the top portion.
4. A showerhead assembly configured to deliver a plurality of gases into a cyclic deposition chamber, the showerhead assembly comprising:
   a showerhead comprising a vertical cavity formed through a central region and a main inner surface configured to face a substrate, wherein the main inner surface radially surrounds the vertical cavity;
   an injector block assembly disposed over the showerhead for delivering the gases from outside of the cyclic deposition chamber into the cyclic deposition chamber through the vertical cavity; and
   a plurality of gas channels formed in the injector block assembly configured to flow one or more of the gases separately at least partly through the injector block assembly,
   a premix chamber formed in the injector block assembly, the premix chamber configured to receive the gases separately through the gas channels and to premix the gases therein to form a gas mixture before the gas mixture is delivered to the vertical cavity.
5. The showerhead assembly of Embodiment 2, 3 or 4, wherein the gas channels exiting the injector block assembly extend in different directions relative to each other and to a vertical axis crossing the substrate.
6. The showerhead assembly of Embodiment 1, 3 or 4, wherein a neck angle formed between the main surface and a horizontal plane parallel to a main surface of the substrate is 2-7 degrees.
7. The showerhead assembly of Embodiment 1, 2 or 4, wherein the vertical cavity has a volume having a shape of a truncated cone, wherein the gases enter vertical cavity through a narrower top portion and exits into the cyclic deposition chamber through a base portion of the truncated cone.
8. The showerhead assembly of Embodiments 1, 2 or 3, wherein the injector block assembly further comprises a premix chamber formed therein and configured to receive thereinto the gases separately through the gas channels and to premix the gases therein to form a gas mixture that is delivered to the vertical cavity.
9. The showerhead assembly of any one of the Embodiments, wherein the main inner surface of the showerhead is tapered such that a vertical distance from the substrate to the main inner surface decreases in a radially outward direction relative a center of the substrate.
10. The showerhead assembly of any one of the Embodiments, wherein the gas channels exiting the injector block assembly extend in different directions.
11. The showerhead assembly of Embodiment 10, wherein the different directions are angled relative to a vertical axis of the cyclic deposition chamber and do not directly cross a main surface of the substrate.
12. The showerhead assembly of any one of the above Embodiments, wherein different ones of the plurality of gas channels are configured to flow gases or gas mixtures that are different from each other.
13. The showerhead assembly of any one of the above Embodiments, wherein the vertical cavity has a curved inner sidewall that continuously form part of an inner surface of the showerhead with the main inner surface.
14. The showerhead assembly of any one of the above Embodiments, wherein the vertical cavity has a curved sidewall having a shape of an inner lateral surface of a truncated cone having a cone angle of 8-12 degrees relative to a vertical axis of the cyclic deposition chamber.
15. The showerhead assembly of any one of the above Embodiments, wherein the injector block assembly has an upper surface having openings of the gas channels configured to receive gases from a plurality of gas lines, and a lower surface coupled to a top opening of the vertical cavity to flow the gases thereinto.
16. The showerhead assembly of any one of the above Embodiments, wherein a solid body portion of the showerhead has the main surface configured to face the substrate that has a constant slope relative a main surface of the substrate such that a thickness of the solid body portion increases towards an edge region of the solid body portion.
17. The showerhead assembly of any one of the above Embodiments, wherein the vertical cavity extends through an entire thickness of the showerhead at the central region.
18. The showerhead assembly of any one of the above Embodiments, wherein the gas channels are configured such that the gases enter the vertical cavity at a vertical depth, toward the substrate, from a top opening of the vertical cavity.
19. The showerhead assembly of Embodiment 18, wherein the gas channels are configured such that the gases flowing through different ones of the gas channels flow separately into the vertical cavity without mixing prior to being delivered into the vertical cavity.
20. The showerhead assembly of Embodiment 18 or 19, wherein the gas channels exiting the injector block assembly extend in different directions crossing different sidewall portions of the vertical cavity.
21. The showerhead assembly of any one of Embodiments 18-20, wherein the gas channels are configured such that different gases exit the injector block assembly at different vertical depths of the vertical cavity.
22. The showerhead assembly of any one of Embodiments 18-21, wherein the injector block assembly comprises a protruding portion protruding vertically into the vertical cavity, and the gas channels extend into the protruding portion such that the gases exit from the protruding portion at a vertical depth into the vertical cavity.
23. The showerhead assembly of Embodiment 22, wherein the protruding portion comprises a solid cylindrical portion having the gas channels extending therein.
24. The showerhead assembly of any one of Embodiments 18-23, wherein each of the gas channels extending into the protruding portion comprise a main channel that branches out into a plurality of exit channels that a corresponding gas finally passes through before entering the vertical cavity.
25. The showerhead assembly of Embodiment 24, wherein the exit channels extend outward from the main channel.
26. The showerhead assembly of Embodiment 24 or 25, wherein the exit channels extend in a horizontal direction parallel to a main surface of the substrate.
27. The showerhead assembly any one of Embodiments 24-26, wherein the exit channels for different gases exit the protruding portion at different vertical depths into the vertical cavity.
28. The showerhead assembly of any one of Embodiments 1-17, further comprising a premix chamber extends from a lower surface of the injector block assembly into the vertical cavity.
29. The showerhead assembly of any one of the above Embodiments, wherein the gas channels are configured such that one or more of the gases flowing through different ones of the gas channels flow separately into the premix chamber without mixing prior to being delivered into the premix chamber.
30. The showerhead assembly of any one of the above Embodiments, wherein the gas channels are configured such that the gases enter the vertical cavity at a vertical depth from a top opening of the vertical cavity toward the substrate.
31. The showerhead assembly of Embodiment 28 or 29, wherein the gas channels exiting the injector block assembly extend in different directions crossing different sidewall portions of the premix chamber.
32. The showerhead assembly of any one of Embodiments 28-31, wherein the premix chamber comprises a top opening coupled directly to the injector block assembly for receiving the gases directly therefrom.
33. The showerhead assembly of any one of Embodiments 28-32, wherein the premix chamber comprises a hollow cavity having formed through a sidewall thereof one or more exit channels.
34. The showerhead assembly of any one of Embodiments 28-33, wherein the hollow cavity is defined by a bottom wall and the sidewall connecting a bottom surface of the injector block assembly and the bottom wall.
35. The showerhead assembly of Embodiment 34, wherein the gas channels exiting the injector block assembly extend in different directions crossing different portions of the bottom wall.
36. The showerhead assembly of any one of Embodiments 28-35, wherein the hollow cavity has a cylindrical shape having a curved sidewall.
37. The showerhead assembly of any one of Embodiments 28-36, wherein the premix chamber comprises one or more exit channels formed through a lower portion of the sidewall.
38. The showerhead assembly of Embodiment 37, wherein the exit channels extend outward from the hollow cavity.
39. The showerhead assembly of Embodiments 37 or 38, wherein the exit channels extend in a horizontal direction parallel to a main surface of the substrate.
40. The showerhead assembly of any one of Embodiments 37-39, wherein the exit channels surround the hollow cavity of the premix chamber.
41. The showerhead assembly of any one of Embodiments 37-40, wherein the exit channels are formed at the same vertical level.
42. The showerhead assembly of any one of Embodiments 1-17, further comprising a premix chamber formed within the injector block assembly.
43. The showerhead assembly of Embodiment 42, wherein the premix chamber is formed as a recessed cavity in the injector block assembly.
44. The showerhead assembly of Embodiment 42 or 43, wherein the gas channels are configured such that one or more of the gases flowing through different ones of the gas channels flow separately into the premix chamber without mixing prior to being delivered into the premix chamber.
45. The showerhead assembly of any one of the Embodiments 42-44, wherein the gas channels are configured such that the gases enter the premix chamber at a top opening thereof.
46. The showerhead assembly of any one of the Embodiment 42-45, wherein the gas channels exiting the injector block assembly into the premix chamber extend in different directions.
47. The showerhead assembly of any one of Embodiments 42-46, further comprising a diffuser plate separating the premix chamber and the vertical cavity.
48. The showerhead assembly of Embodiment 47, wherein the diffuser plate is a porous plate configured such that the gases entering the premix chamber substantially mix prior to exiting the premix chamber and into the vertical cavity.
49. The showerhead assembly of Embodiment 47 or 48, wherein the gas channels exiting the injector block assembly extend in different directions crossing different portions of the diffuser plate.
50. The showerhead assembly of any one of Embodiments 47-49, wherein the diffuser plate comprises a plurality of holes having a diameter substantially smaller than diameters of the gas channels.
51. The showerhead assembly of any one of Embodiments 42-50, wherein the premix chamber has a dome shape having a curved inner surface.
52. The showerhead assembly of any one of Embodiments 42-51, wherein the mixing chamber is disposed above the vertical cavity and does not vertically overlap therewith.
53. The showerhead assembly of any one of the above Embodiments, wherein the showerhead assembly is further according to any one of the showerhead assemblies in EXAMPLE EMBODIMENTS III.

### Example Embodiments II

1. A showerhead assembly configured to deliver a plurality of gases into a cyclic deposition chamber, the showerhead assembly comprising:
   a showerhead comprising a main inner surface configured to face a substrate, wherein the main inner surface surrounds a vertical cavity formed at a central region thereof through which the gases are delivered into the cyclic deposition chamber;
   an injector block assembly disposed over the showerhead and configured to receive the gases through external gas lines connected thereto and having a plurality of injection nozzles for delivering the gases into the cyclic deposition chamber through the vertical cavity; and
   a premix chamber formed in the injector block assembly, the premix chamber configured to premix the gases received from the gas lines to form a gas mixture therein before the gas mixture is delivered to the vertical cavity,
   wherein an internal volume of the premix chamber has a constricted portion that constricts the gas mixture prior to delivering the gas mixture to the vertical cavity.
2. A showerhead assembly configured to deliver a plurality of gases into a cyclic deposition chamber, the showerhead assembly comprising:
   a showerhead comprising a main inner surface configured to face a substrate, wherein the main inner surface surrounds a vertical cavity formed at a central region thereof through which the gases are delivered into the cyclic deposition chamber;
   an injector block assembly disposed over the showerhead and configured to receive the gases through external gas lines connected thereto and having a plurality of injection nozzles for delivering the gases into the cyclic deposition chamber through the vertical cavity; and
   a premix chamber formed in the injector block assembly, the premix chamber configured to premix the gases received from the gas lines to form a gas mixture therein before the gas mixture is delivered to the vertical cavity, wherein the premix chamber has a lower portion comprising a plurality of nozzles for injecting the gas mixture into the vertical cavity.
3. A showerhead assembly configured to deliver a plurality of gases into a cyclic deposition chamber, the showerhead assembly comprising:
   a showerhead comprising a main inner surface configured to face a substrate, wherein the main inner surface surrounds a vertical cavity formed at a central region thereof through which the gases are delivered into the cyclic deposition chamber;
   an injector block assembly disposed over the showerhead and configured to receive the gases through external gas lines connected thereto and having a plurality of injection nozzles for delivering the gases into the cyclic deposition chamber through the vertical cavity; and
   a premix chamber formed in the injector block assembly, the premix chamber configured to premix the gases received from the gas lines to form a gas mixture therein before the gas mixture is delivered to the vertical cavity,
   wherein a neck angle formed between the main surface and a horizontal plane parallel to a main surface of the substrate is 2-7 degrees.
4. A showerhead assembly configured to deliver a plurality of gases into a cyclic deposition chamber, the showerhead assembly comprising:
   a showerhead comprising a main inner surface configured to face a substrate, wherein the main inner surface surrounds a vertical cavity formed at a central region thereof through which the gases are delivered into the cyclic deposition chamber;
   an injector block assembly disposed over the showerhead and configured to receive the gases through external gas lines connected thereto and having a plurality of injection nozzles for delivering the gases into the cyclic deposition chamber through the vertical cavity; and
   a premix chamber formed in the injector block assembly, the premix chamber configured to premix the gases received from the gas lines to form a gas mixture therein before the gas mixture is delivered to the vertical cavity,
   wherein the vertical cavity has a volume having a shape of a truncated cone, wherein the gases enter vertical cavity through a narrower top portion and exits into the cyclic deposition chamber through a base portion of the truncated cone.
5. The showerhead assembly of Embodiment 2, 3 or 4, wherein an internal volume of the premix chamber has a constricted portion that constricts the gas mixture prior to delivering the gas mixture to the vertical cavity.
6. The showerhead assembly of Embodiment 1, 3, or 4, wherein the premix chamber has a lower portion comprising a plurality of nozzles for injecting the gas mixture into the vertical cavity.
7. The showerhead assembly of Embodiment 1, 2, or 4, wherein a neck angle formed between the main surface and a horizontal plane parallel to a main surface of the substrate is 2-7 degrees.
8. The showerhead assembly of Embodiment 1, 2, or 3 wherein the vertical cavity has a volume having a shape of a truncated cone, wherein the gases enter vertical cavity through a narrower top portion and exits into the cyclic deposition chamber through a base portion of the truncated cone.
9. The showerhead assembly of any of the above Embodiments, wherein the internal volume of the premix chamber has the constriction portion vertically disposed between wider portions such that the premix chamber has an hourglass shape.
10. The showerhead assembly of any of the above Embodiments, wherein nozzles at a lower portion of the premix chamber comprise channels extending substantially parallel to a major surface of the substrate.
11. The showerhead assembly of any of Embodiments 1-9, wherein nozzles at a lower portion of the premix chamber comprise channels extending in directions at a vertical angle relative to a major surface of the substrate.
12. The showerhead assembly of any of the above Embodiments, wherein nozzles at a lower portion of the premix chamber comprise channels extending in directions at a horizontal angle relative to a radial direction from a central axis of the premix chamber.
13. The showerhead assembly of any one of the Embodiments, wherein the main inner surface of the showerhead is tapered such that a vertical distance from the substrate to the main inner surface decreases in a radially outward direction relative a center of the substrate.
14. The showerhead assembly of any one of the above Embodiments, wherein the vertical cavity has a curved inner sidewall that continuously forms part of an inner surface of the showerhead with the main inner surface.
15. The showerhead assembly of any one of the above Embodiments, wherein the vertical cavity has a curved sidewall having a shape of an inner lateral surface of a truncated cone having a cone angle of 8-12 degrees relative to a vertical axis of the cyclic deposition chamber.
16. The showerhead assembly of any one of the above Embodiments, wherein the injector block assembly has an upper surface having openings configured to receive gases from a plurality of gas lines, and a lower surface coupled to a top opening of the vertical cavity to flow the gases thereinto.
17. The showerhead assembly of any one of the above Embodiments, wherein a solid body portion of the showerhead has the main surface configured to face the substrate that has a constant slope relative a main surface of the substrate such that a thickness of the solid body portion increases towards an edge region of the solid body portion.
18. The showerhead assembly of any one of the above Embodiments, wherein the vertical cavity extends through an entire thickness of the showerhead at the central region.
19. The showerhead assembly of any one of the above Embodiments, wherein the injector block assembly has formed therein gas channels configured such that the gases flowing through different ones of the gas channels flow separately into the vertical cavity without mixing prior to being delivered into the vertical cavity.
20. The showerhead assembly of any one of the above Embodiments, wherein the injection nozzles exiting the premix chamber extend in different directions crossing different sidewall portions of the vertical cavity.
21. The showerhead assembly of Embodiment 20, wherein the injection nozzles exit the premix chamber at different vertical depths of the vertical cavity.
22. The showerhead assembly of any one of the above Embodiments, wherein the injector block assembly comprises a protruding portion protruding vertically into the vertical cavity, and the injector nozzles extend into the protruding portion such that the gases exit from the protruding portion at a vertical depth into the vertical cavity.
23. The showerhead assembly of Embodiment 22, wherein the protruding portion comprises a solid cylindrical portion having the gas channels extending therein.
24. The showerhead assembly of any one of the above Embodiments, wherein the injection nozzles extend in a horizontal direction parallel to a main surface of the substrate.
25. The showerhead assembly any one of the above Embodiments, wherein the injection nozzles exit the protruding portion at different vertical depths into the vertical cavity.
26. The showerhead assembly of any one of the above Embodiments, wherein the injector block assembly has formed therein gas channels configured such that one or more of the gases flowing through different ones of the gas channels flow separately into the premix chamber without mixing prior to being delivered into the premix chamber.
27. The showerhead assembly of any one of the above Embodiments, wherein the gas channels are configured such that the gases enter the vertical cavity at a vertical depth from a top opening of the vertical cavity toward the substrate.
28. The showerhead assembly of any one of the above Embodiments, wherein the injection nozzles exiting the premix chamber extend in different directions crossing different sidewall portions of the vertical cavity.
29. The showerhead assembly of any one of the above Embodiments, wherein the premix chamber comprises a top opening coupled directly to the injector block assembly for receiving the gases directly therefrom.
30. The showerhead assembly of any one of the above Embodiments, wherein the premix chamber comprises a hollow cavity having formed through a sidewall thereof one or more exit channels.
31. The showerhead assembly of Embodiment 30, wherein the hollow cavity is defined by a bottom wall and the sidewall connecting a bottom surface of the injector block assembly and the bottom wall.
32. The showerhead assembly of any one of the above Embodiments, further comprising a diffuser plate separating the premix chamber and the vertical cavity.
33. The showerhead assembly of Embodiment 32, wherein the diffuser plate is a porous plate configured such that the gases entering the premix chamber substantially mix prior to exiting the premix chamber and into the vertical cavity.
34. The showerhead assembly of Embodiment 32 or 33, wherein the gas channels exiting the injector block assembly extend in different directions crossing different portions of the diffuser plate.
35. The showerhead assembly of any one of Embodiments 32-34, wherein the diffuser plate comprises a plurality of holes having a diameter substantially smaller than diameters of the gas channels.
36. The showerhead assembly of any one of the above Embodiments, wherein the premix chamber has a dome shape having a curved inner surface.
37. The showerhead assembly of any one of the above Embodiments, wherein the premixing chamber is disposed above the vertical cavity and does not vertically overlap therewith.
38. The showerhead assembly of any one of the above Embodiments, wherein the showerhead assembly is further according to any one of the showerhead assemblies in EXAMPLE EMBODIMENTS III.

### Example Embodiments III

1. A showerhead assembly configured to deliver a plurality of gases into a cyclic deposition chamber, the showerhead assembly comprising:
   a showerhead comprising a main inner surface configured to face a substrate, wherein the main inner surface surrounds a vertical cavity formed at a central region thereof through which the gases are delivered into the cyclic deposition chamber;
   an injector block assembly disposed over the showerhead and configured to receive the gases through external gas lines connected thereto and having a plurality of injection nozzles for delivering the gases into the cyclic deposition chamber through the vertical cavity; and
   a diffuser plate substantially overlapping a lateral footprint of the showerhead and disposed vertically between the showerhead and the substrate, the diffuser plate comprising a plurality of holes for diffusing the gases received from the vertical cavity prior to the gases reaching the substrate.
2. A showerhead assembly configured to deliver a plurality of gases into a cyclic deposition chamber, the showerhead assembly comprising:
   a showerhead comprising a main inner surface configured to face a substrate, wherein the main inner surface surrounds a vertical cavity formed at a central region thereof through which the gases are delivered into the cyclic deposition chamber;
   an injector block assembly disposed over the showerhead and configured to receive the gases through external gas lines connected thereto and having a plurality of injection nozzles for delivering the gases into the cyclic deposition chamber through the vertical cavity; and a blocking plate disposed laterally at the central region and vertically between the injection nozzles and the substrate.
3. A showerhead assembly configured to deliver a plurality of gases into a cyclic deposition chamber, the showerhead assembly comprising:
   a showerhead comprising a main inner surface configured to face a substrate, wherein the main inner surface surrounds a vertical cavity formed at a central region thereof through which the gases are delivered into the cyclic deposition chamber; and
   an injector block assembly disposed over the showerhead and configured to receive the gases through external gas lines connected thereto and having a plurality of injection nozzles for delivering the gases into the cyclic deposition chamber through the vertical cavity,
   wherein the main inner surface of the showerhead forms an angle, with respect to a main surface of the substrate, that is different at different radial distances from a central axis of the showerhead.
4. A showerhead assembly configured to deliver a plurality of gases into a cyclic deposition chamber, the showerhead assembly comprising:
   a showerhead comprising a main inner surface configured to face a substrate, wherein the main inner surface surrounds a vertical cavity formed at a central region thereof through which the gases are delivered into the cyclic deposition chamber; and
   an injector block assembly disposed over the showerhead and configured to receive the gases through external gas lines connected thereto and having a plurality of injection nozzles for delivering the gases into the cyclic deposition chamber through the vertical cavity,
   wherein a vertical gap between the main inner surface of the showerhead and a main surface of the substrate changes nonlinearly with radial distance from a central axis of the showerhead.
5. The showerhead assembly of Embodiment 2, 3 or 4, further comprising a diffuser plate substantially overlapping a lateral footprint of the showerhead and disposed vertically between the showerhead and the s substrate, the diffuser plate comprising a plurality of holes for diffusing the gases received from the vertical cavity prior to the gases reaching the substrate.
6. The showerhead assembly of Embodiments 1, 3 or 4, further comprising a blocking plate disposed laterally at the central region and vertically between the injection nozzles and the substrate.
7. The showerhead assembly of Embodiments 1, 2 or 4, wherein the main inner surface of the showerhead forms an angle, with respect to a main surface of the substrate, that is different at different radial distances from a central axis of the showerhead.
8. The showerhead assembly of Embodiments 1, 2, or 3, wherein a vertical gap between the main inner surface of the showerhead and a main surface of the substrate changes nonlinearly with radial distance from a central axis of the showerhead.
9. The showerhead assembly of any one of the above Embodiments, wherein the holes of the diffuser plate substantially cover an entire area of thereof.
10. The showerhead assembly of any one of Embodiments 1-8, wherein the holes of the diffuser plate laterally overlap the central region of the main inner surface while being omitted from an outer region of the diffuser plate corresponding to outer 20% of a radius of the diffuser plate.
11. The showerhead assembly of any one of the above Embodiments, wherein the holes form a random pattern.
12. The showerhead assembly of any one of the above Embodiments, wherein the holes form a regular pattern including a substantially constant distance between adjacent holes or adjacent groups of holes.
13. The showerhead assembly of Embodiment 12, wherein the regular pattern comprises a rectangular array including rows having a substantially constant inter-row distance and columns having a substantially constant inter-column distance.
14. The showerhead assembly of Embodiment 12, wherein the regular pattern comprises a circular array including a plurality of rings each having a plurality of holes at a constant radius.
15. The showerhead assembly of Embodiment 14, wherein the holes of adjacent ones of the rings lie on a common radial line extending outward from a center of the diffuser plate.
16. The showerhead assembly of Embodiment 14, wherein the holes of adjacent ones of the rings do not lie on a common radial line extending outward from a center of the diffuser plate.
17. The showerhead assembly of any one of the above Embodiments, wherein the diffuser plate comprises a plurality of concentric radial zones, wherein different radial zones have differently arranged holes.
18. The showerhead assembly of Embodiment 17, wherein different radial zones have different area density of holes.
19. The showerhead assembly of Embodiments 17 or 18, wherein different radial zones have different size of holes.
20. The showerhead assembly of any one of Embodiments 17-19, wherein one or both of the area density and the size of the holes increase with increasing distance from a central axis of the showerhead.
21. The showerhead assembly of any one of the above Embodiments, wherein the blocking plate is vertically disposed between the injection nozzles and the diffuser plate.
22. The showerhead assembly of any one of the above Embodiments, wherein the blocking plate has a lateral dimension that is smaller than a smallest lateral dimension of the vertical cavity.
23. The showerhead assembly of any one of the above Embodiments, wherein the blocking plate is at least partially vertically inserted into the vertical cavity.
24. The showerhead assembly of any one of the above Embodiments, wherein the blocking plate comprises a cylindrical portion having a vertical length extending in a vertical direction substantially greater than a diameter thereof.
25. The showerhead assembly of any one of Embodiments 1-20, wherein the blocking plate comprises a cylindrical portion having a vertical length extending in a vertical direction substantially smaller than a diameter thereof.
26. The showerhead assembly of any one of the above Embodiments, wherein the blocking plate is attached to the diffuser plate.
27. The showerhead assembly of any one of the above Embodiments, wherein the main inner surface of the showerhead forms the angle, with respect to the main surface of the substrate, that decreases in the radial direction from the central axis of the showerhead.
28. The showerhead assembly of any one of the above Embodiments, wherein the main inner surface of the showerhead forms the angle, with respect to the main surface of the substrate, that continuously decreases in the radial direction from the central axis of the showerhead.
29. The showerhead assembly of any one of the Embodiments, wherein a vertical gap between the main inner surface of the showerhead and a main surface of the substrate decreases in the radial direction.
30. The showerhead assembly of any one of the Embodiments, wherein a vertical gap between the main inner surface of the showerhead and a main surface of the substrate decreases continuously in the radial direction.
31. The showerhead assembly of any one of the Embodiments, wherein an outer portion of the main inner surface of the showerhead is substantially parallel to the main surface of the substrate.
32. The showerhead assembly of any one of the Embodiments, a vertical gap between an outer portion of the main inner surface of the showerhead and a main surface of the substrate is substantially constant.
33. The showerhead assembly of any one of the above Embodiments, wherein the vertical cavity has a volume having a shape of a truncated cone, wherein the gases enter vertical cavity through a narrower top portion and exits into the cyclic deposition chamber through a base portion of the truncated cone.
34. The showerhead assembly of any one of the above Embodiments, wherein the showerhead assembly is further according to any one of the showerhead assemblies in EXAMPLE EMBODIMENTS I or EXAMPLE EMBODIMENTS II.

### Additional Considerations

Although the present invention has been described herein with reference to the specific embodiments, these embodiments do not serve to limit the invention and are set forth for illustrative purposes. It will be apparent to those skilled in the art that modifications and improvements can be made without departing from the spirit and scope of the invention.

Such simple modifications and improvements of the various embodiments disclosed herein are within the scope of the disclosed technology, and the specific scope of the disclosed technology will be additionally defined by the appended claims.

In the foregoing, it will be appreciated that any feature of any one of the embodiments can be combined or substituted with any other feature of any other one of the embodiments.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number, respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while features are presented in a given arrangement, alternative embodiments may perform similar functionalities with different components and/or sensor topologies, and some features may be deleted, moved, added, subdivided, combined, and/or modified. Each of these features may be implemented in a variety of different ways. Any suitable combination of the elements and acts of the various embodiments described above can be combined to provide further embodiments. The various features and processes described above may be implemented independently of one another, or may be combined in various ways. All possible combinations and subcombinations of features of this disclosure are intended to fall within the scope of this disclosure.

What is claimed is:

1. A showerhead assembly configured to deliver a plurality of gases into a cyclic deposition chamber, the showerhead assembly comprising:
a showerhead comprising a vertical cavity formed through a central region and a main inner surface configured to face a substrate, wherein the main inner surface radially surrounds the vertical cavity;
an injector block assembly disposed over the showerhead for delivering the gases from outside of the cyclic deposition chamber into the cyclic deposition chamber through the vertical cavity; and
a plurality of gas channels formed in the injector block assembly and configured to flow the gases separately at least partly through the injector block assembly,
wherein the gas channels exiting the injector block assembly extend in different directions relative to each other and to a vertical axis crossing the substrate.

2. The showerhead assembly of claim 1, wherein a neck angle formed between the main surface and a horizontal plane parallel to a main surface of the substrate is 2-7 degrees.

3. The showerhead assembly of claim 1, wherein the vertical cavity has a volume having a shape of a truncated cone, wherein the gases enter the vertical cavity through a narrower top portion and exits into the cyclic deposition chamber through a base portion of the truncated cone wider than the top portion.

4. The showerhead assembly of claim 1, wherein the injector block assembly further comprises a premix chamber formed therein and configured to receive thereinto the gases separately through the gas channels and to premix the gases therein to form a gas mixture that is delivered to the vertical cavity.

5. The showerhead assembly of claim 1, wherein the main inner surface of the showerhead is tapered such that a vertical distance from the substrate to the main inner surface decreases in a radially outward direction relative a center of the substrate.

6. The showerhead assembly of claim 1, wherein different ones of the plurality of gas channels are configured to flow gases or gas mixtures that are different from each other.

7. The showerhead assembly of claim 1, wherein the vertical cavity has a curved sidewall having a shape of an inner lateral surface of a truncated cone having a cone angle of 8-12 degrees relative to a vertical axis of the cyclic deposition chamber.

8. The showerhead assembly of claim 1, wherein the gas channels are configured such that the gases enter the vertical cavity at a vertical depth, toward the substrate, from a top opening of the vertical cavity.

9. The showerhead assembly of claim 8, wherein the gas channels are configured such that the gases flowing through different ones of the gas channels flow separately into the vertical cavity without mixing prior to being delivered into the vertical cavity.

10. The showerhead assembly of claim 4, wherein the premix chamber is formed as a recessed cavity in the injector block assembly.

11. The showerhead assembly of claim 10, wherein the gas channels are configured such that one or more of the gases flowing through different ones of the gas channels flow separately into the premix chamber without mixing prior to being delivered into the premix chamber.

12. The showerhead assembly of claim 10, wherein the gas channels are configured such that the gases enter the premix chamber at a top opening thereof.

13. The showerhead assembly of claim 10, wherein the gas channels exiting the injector block assembly into the premix chamber extend in different directions.

14. A showerhead assembly configured to deliver a plurality of gases into a cyclic deposition chamber, the showerhead assembly comprising:
a showerhead comprising a vertical cavity formed through a central region and a main inner surface configured to face a substrate, wherein the main inner surface radially surrounds the vertical cavity;
an injector block assembly disposed over the showerhead for delivering the gases from outside of the cyclic deposition chamber into the cyclic deposition chamber through the vertical cavity; and
a plurality of gas channels formed in the injector block assembly configured to flow one or more of the gases separately at least partly through the injector block assembly,
a premix chamber formed in the injector block assembly, the premix chamber configured to receive the gases separately through the gas channels and to premix the gases therein to form a gas mixture before the gas mixture is delivered to the vertical cavity.

15. The showerhead assembly of claim 14, wherein the premix chamber comprises a hollow cavity having formed through a sidewall thereof one or more exit channels.

16. The showerhead assembly of claim 15, wherein the hollow cavity is defined by a bottom wall and the sidewall connecting a bottom surface of the injector block assembly and the bottom wall.

17. The showerhead assembly of claim 16, wherein the gas channels exiting the injector block assembly extend in different directions crossing different portions of the bottom wall.

18. The showerhead assembly of claim 15, wherein the hollow cavity has a cylindrical shape having a length extending in a vertical direction.

19. The showerhead assembly of claim 15, wherein the premix chamber comprises one or more exit channels formed through a lower portion of the sidewall.

20. The showerhead assembly of claim 19, wherein the exit channels extend outward from the hollow cavity.

21. The showerhead assembly of claim 19, wherein the exit channels extend in a horizontal direction parallel to a main surface of the substrate.

22. The showerhead assembly of claim 19, wherein the exit channels surround the hollow cavity of the premix chamber.

23. The showerhead assembly of claim 19, wherein the exit channels are formed at a same vertical level.
